(19) United States
(12) Patent Application Publication
(10) Pub. No.: US 2024/0415009 A1
(43) Pub. Date: Dec. 12, 2024

(54) PEROVSKITE MATERIALS AND THEIR USE IN PHOTOVOLTAIC DEVICES

(71) Applicant: OXFORD PHOTOVOLTAICS LIMITED, Yarnton, Oxfordshire (GB)

(72) Inventors: Christina KAMARAKI, Yarnton, Oxfordshire (GB); Laura Miranda PEREZ, Yarnton, Oxfordshire (GB); Matthew KLUG, Yarnton, Oxfordshire (GB); Christopher CASE, Yarnton, Oxfordshire (GB); Alice TAYLOR, Yarnton, Oxfordshire (GB)

(21) Appl. No.: 18/697,249

(22) PCT Filed: Sep. 30, 2022
(86) PCT No.: PCT/GB2022/052485

§ 371 Date: Mar. 29, 2024

(30) Foreign Application Priority Data
Sep. 30, 2021 (GB) 2114040.5

(51) Int. Cl. H10K 85/50; C07F 7/24; H10K 30/40

(52) U.S. Cl. CPC H10K 85/50; C07F 7/24; H10K 30/40

(57) ABSTRACT

There is provided a perovskite material A perovskite material having the formula (I): AaA′bA″cSn(y)Pb(1-y)X3 (I) wherein A consists of a monovalent cation; A′ consists of a monovalent organic cation having an ionic radius greater than 2.53 Å; A″ consists of a monovalent inorganic cation; X comprises one or more halide anions; 0<a<1; 0<b<1; 0≤c<1; a+b+c=1; and 0<y<1. Also provided is a semiconductor device having a photoactive region comprising a perovskite material as defined herein; a semiconductor device which is a photovoltaic device; and a multijunction photovoltaic device comprising two or more sub-cells, wherein the first sub cell comprises a photovoltaic device as defined herein and a further sub-cell comprising a photoactive layer having a bandgap of between 1.5 and 1.9 eV.

### FIELD OF THE INVENTION

The present invention relates to perovskite materials comprising Pb and Sn cations together with selected other cations, and to single-junction and multi-junction photovoltaic devices using such materials in light absorbing layers.

### BACKGROUND OF THE INVENTION

Solar energy conversion is one of the most promising technologies to provide renewable energy.

One class of photovoltaic materials that has attracted significant recent interest has been organic-inorganic halide perovskites. Materials of this type have a perovskite crystal structure with general formula ABX₃. These materials have been found to exhibit favourable band gaps, high absorption coefficients and long diffusion lengths, rendering such compounds ideal as an absorber in photovoltaic devices.

The maximum efficiency of a single junction solar cell is between 33.7% to 31% under AM1.5 solar spectrum illumination when the band gap is within the range of 1.4 to 1.1 eV. Lead (Pb) based organic-inorganic halide perovskites have demonstrated efficiencies as high as 25.2%, but have band gaps larger than this ideal value: typically in the range 1.5 to 1.8 eV.

Tin (Sn) based organic-inorganic halide perovskites such as methylammonium tin iodide have energy gaps closer to the ideal values of 1.23 to 1.41 eV, allowing better light harvesting than their lead counterparts (Leijtens et al., “Tin-lead halide perovskites with improved thermal and air stability for efficient all-perovskite tandem solar cells”, Sustain. Energy Fuels, 2018, 00, 1-10). However, due to the easier oxidation of tin, tin-based perovskites are more vulnerable to oxidation in air than their lead counterparts, and can oxidatively degrade even if processed in an inert atmosphere. In addition, despite having similar optoelectronic properties to Pb-based perovskites, in general it is difficult to achieve efficiencies in excess of 10% with solar cells based on Sn (Xi et al. “Scalable, Template Driven Formation of Highly Crystalline Lead-Tin Halide Perovskite Films” Advanced Functional Materials, Early View, 2105734, 2021).

As mentioned above, Sn-based perovskites are more liable to oxidise than their Pb-based equivalents. The presence of Sn in the films adds extra instability due to its multivalent nature. Sn²⁺ tends to oxidize to Sn⁴⁺ after exposure to oxygen resulting in p-type doping of the material that is undesirable for photovoltaic applications. It is also thought that the diffusion of O₂ starts at the surface and through the grain boundaries and thus various strategies have been employed to hinder oxidation. The most popular strategies to improve stability involve the use of compounds, such as Lewis bases that can form an adduct with SnF₂—usually used as a Sn²⁺ “reservoir” to compensate Sn⁴⁺—ensuring its homogeneous distribution at the grain boundaries. Most of these adducts, such as hydroquinone sulfonic acid or 2-aminophenol-4-sulfonic acid have a second function as an antioxidant since they contain hydroxyl groups (—OH) that act as O₂ scavengers, as found by Tai et al. (“Antioxidant Grain Passivation for Air-Stable Tin-Based perovskite solar cells”, Angew. Chem./nt. Ed. 2019, 58, 806-810). Wang et al. (“Highly Air-Stable Tin-Based perovskite Solar Cells through Grain-Surface Protection by Gallic Acid”, ACS Energy Lett. 2020, 5, 6, 1741-749) also found that gallic acid forms a complex with SnX₂, able to protect the perovskite grains and effectively conduct electrons across it. In addition, various large molecules that form 2D perovskite structures have been used as a post-treatment or for in-film passivation of the surface and grain boundaries, an approach that has been adopted from the Pb-counterparts. Often the SnF₂ is mixed in with the perovskite precursor solution, for example in spin-coating. These approaches are highly dependent on the process and they do not improve the intrinsic stability of the material; rather, they use external factors to limit the oxidation/degradation.

Mixed Pb/Sn compositions have been investigated in order to optimise the band gap, efficiency and the stability of the material. The electrical characteristics of solar cells featuring different Sn/Pb absorbers have been compared (Konstantakou et al., “A critical review on tin halide perovskites”, J. Mater. Chem. A., 2017, 5, 11518-11549). It was observed that increasing the Sn content increases nonradiative recombination in the cell, regulating its operation and causing a decrease in V_{oc}. An equivalent effect was also seen for efficiency.

Interestingly, it has been found that mixed Sn—Pb perovskites follow a different oxidation pathway to that of neat Sn-perovskites, with the main oxidation products being I₂, SnO₂ and PbI₂. This alternative degradation route proceeds more slowly than for neat Sn-perovskites.

Sn—Pb perovskite solar cells display high performances with efficiencies up to 21.74% as reported by Kapil et al. (“Tin-Lead Perovskite Fabricated via Ethylenediamine Interlayer Guides to the Solar Cell Efficiency of 21.74%”, Advanced Energy Materials, Vol. 11, 25, 2021) and greater durability, making them promising candidates not only for single junction solar cells but also for all perovskite tandem configurations as the narrow bandgap absorber material. MASn_{0.5}Pb_{0.5}I₃, FASn_{0.5}Pb_{0.5}I₃, FA_{0.75}Cs_{0.25}Sn_{0.5}Pb_{0.5}I₃ and FA_{0.6}MA_{0.4}Sn_{0.6}Pb_{0.4}I₃(FA: formamidinium; MA: methylammonium) have been studied extensively in terms of devices (Leijtens et al., Sustain. Energy Fuels, 2018 and Zhao et al., “Low-bandgap mixed tin-lead iodide perovskite absorbers with long carrier lifetimes for all-perovskite tandem solar cells”, Nat. Energy, 2017, 17018:1-7).

However, problems remain with such materials. For example, FA:Cs compounds are liable to phase separate, and FA:MA compounds can possess low thermal stability. Also, synthesising Sn-containing compounds is more complex, as a reducing agent is often required.

The relative proportion of Sn is also important, as for example lower proportions of Sn (around 6%) have been shown to exhibit poorer optoelectronic qualities, as demonstrated by Klug et al. (“Metal composition influences optoelectronic quality in mixed-metal lead-tin triiodide perovskite solar absorbers”, Energy Environ. Sci. 2020, 13, 1776-1787). In addition, films made from such compounds may have poor crystallinity, leading to enhanced nonradiative recombination. For these reasons, there is a range of band gap energies between 1.4 and 1.6 eV where it has proved difficult to synthesise high-quality films for device applications.

There remains a desire to find alternative compositions to better control the morphology, increase the stability, and reduce the degradation of perovskite materials. There also remains a desire to find alternative synthetic routes which do not use reductants in the solution. Perovskite materials comprising three different A-site cations are attractive for the additional tunability imparted by the third A-site cation. Through the use of careful structural control during synthesis, better blends of perovskite materials can be produced with optimised properties. Perovskites with three different A site cations are known for lead-only perovskites. However, the only known triple cation perovskite comprising both Sn and Pb comprises the cations Cs, FA and MA either with a single halide (iodide) or with a double halide (iodide & bromide). For instance, Cs_{0.05}FA_{0.79}MA_{0.16}Pb_{0.664}Sn_{0.336}I_{2.48}Br_{0.52} is known from Bowman et al. (“Microsecond Carrier Lifetimes, Controlled p-doping, and Enhanced Air stability in Low-Bandgap Metal Halide Perovskites”, ACS Energy Lett. 4, 2301-2307, 2019).

WO2018015831A1 discloses a mixed cation perovskite material, wherein more than four A cations are present as a means of stabilising the perovskite material and improving its purity. This application acknowledges that Sn/Pb compositions are oxidation unstable and theorises that this may be improved by using multiple cations and metals. However, no formal process or guidance for specifically stabilising Sn/Pb based perovskites is disclosed. The present invention on the other hand provides unique compositions for stabilising Sn/Pb perovskites, meanwhile reducing the complexity of the system by eliminating the need for excessive amounts A cation sources.

WO2019232643A1 discloses the doping of metal halide perovskites with metals such as lead, cadmium, zinc, manganese, iron, cobalt, nickel, copper and tin to improve the ambient stability of perovskites in solar cell applications. The application particularly focuses on the doping of a CsFAMA based perovskite (Cs_{0.05} MA_{0.15} FA_{0.8} PbI_{2.55} Br_{0.45}) with cadmium metal to release lattice strain. The present invention, however, adopts specific compositions in the A sites of the perovskite combined with a mixture of Pb and Sn occupancy in the B sites to achieve improved material properties.

Weijun et al. disclose the use of ethylenediammonium dications to stabilise three-dimensional hollow Pb/Sn perovskite structures. The diammonium cations, which are too large to fit in the A cage, enter via the formation of B metal vacancies in the perovskite to create space near the A cage and accordingly form a stable hollow framework. However, advances with non-hollow perovskites via A cation site engineering have not been shown.

Song et al. provides a review of the different bandgaps for various Pb/Sn perovskite materials in photovoltaics. However, perovskite material enhancement via occupancy of the A sites with large cations has not been demonstrated.

Zhou et al. (“Highly Efficient and Stable GABr-Modified Ideal-Bandgap (1.35 eV) Sn/Pb Perovskite Solar Cells Achieve 20.63% Efficiency with a Record Small Voc Deficit of 0.33 V” Advanced Materials, Vol. 32, 14, 2020) reported a FA_{0.7}MA_{0.3}Pb_{0.7}Sn_{0.3}I₃ film which was optimised via additive engineering with a small amount of a large cation, guanidinium bromide (GABr). The GA was found to be incorporated into the lattice, incur a change in the bandgap from 1.34 eV to 1.35 eV and impart preferable environmental stability by reducing the defect density caused by Sn²⁺ oxidation.

However, Zhou et al. do not report how much GA is actually incorporated within the lattice nor do they explicitly prove how the GA ions have entered. Furthermore, it is uncertain from this study which of the FA and MA sites are being occupied by the GA and in what proportions. Although a shift is observed in the XRD (FIG. 1b,c), indicating changes to the lattice, it is still unknown how much of this change can be attributed to the small amounts of GA purportedly added in the structure, especially as factors such as perovskite strain due to changes in defect concentrations or vacancies formation within the crystalline structure should also be considered for changes in XRD. Hence, the stoichiometry of the final perovskite structure in Zhou et al. is unknown, as the main purpose of the study was to incorporate GA in minute quantities to serve as an effective passivating agent rather than an intended substitution of either MA or FA in the A sub-lattice of the perovskite.

Conversely, the present invention aims to incorporate such ions in a defined and accurate amount to purposely form a specific, stoichiometric triple cation perovskite structure. By carrying out tolerance factor calculations for the perovskite, the optimised amounts of each A cation can be established to accordingly produce desirably stable, mixed Sn/Pb triple cation perovskites. Such perovskites containing a significant amount of large cations in a mixed Pb/Sn structure are not presently known, especially with respect to triple cations comprising inorganic A cations also.

It is an object of the present invention to provide a new class of mixed Sn—Pb organic-inorganic perovskite materials which have band gap energies in the range 1.2 to 1.6 eV and are suitable for use in semiconductor devices such as photovoltaic devices, single junction solar cells, the bottom cell in all-perovskite tandem solar cells, or the middle cell in all-perovskite or perovskite-perovskite-silicon and perovskite-perovskite-CIGS multijunction solar cells.

The materials of the present invention can mitigate some of the problems associated with the materials known in the art, showing improved crystallinity, thermal stability and providing a preferential crystal orientation in polycrystalline thin films. The materials of the present invention can provide good efficiency when used in solar cells.

### SUMMARY OF THE INVENTION

According to a first aspect of the present invention, there is provided a perovskite material as specified in claims 1 to 20.

In a second aspect, the present invention provides a semiconductor device having a photoactive layer comprising an organic-inorganic metal halide perovskite material according to the first aspect of the invention.

In a third aspect of the invention there is provided a multijunction photovoltaic device comprising two or more sub-cells, the first sub cell comprising a semiconductor device as claimed in the second aspect of the invention, and a further sub-cell comprising a photoactive layer having a bandgap of between 1.5 and 1.9 eV.

It is already known from Pb-based perovskites that the mixing of Methylammonium (MA) with Formamidinium (FA) is necessary to stabilize the unstable black FAPbI₃ trigonal phase (Binek et al. “Stabilization of the Trigonal High-temperature phase of Formamidinium Lead Iodide”, Phys. Chem. Lett., 2015, 6, 7, 1249-1253). However, the introduction of A-cations with larger radii than FA cannot support a 3D perovskite structure as they distort the cavity formed by the inorganic framework, and thus 2D or hexagonal perovskites structures are formed. The mixing of FA/MA has also been adopted successfully for the Pb—Sn compositions. However, the incorporation of larger cations has not been explored yet since it was expected that the Pb—Sn lattice would be smaller than the pure Pb counterparts due to the smaller size of Sn.

The present invention is based on the finding that the A cations in Sn/Pb compositions can be partially replaced by larger cations, thus leading to improved perovskite materials. The discovered perovskites can often be highly crystalline and textured. The materials can also be fine-tuned according to appropriate cation and halide selections, to result in desired band gaps.

### BRIEF DESCRIPTION OF THE FIGURES

Embodiments of the invention will now be described, by way of example only, with reference to the accompanying schematic drawings in which:

FIG. 1 shows the scanning electron microscopy (SEM) images of the different Pb/Sn perovskite compositions based on varied amounts of Sn;

FIG. 2 shows absorption spectra of EA_{0.2}MA_{0.8}SnₓPb₁₋ₓI₃ (x=0-1) (FIG. 2A) and values of optical bandgap as a function of Sn percentage (FIG. 2B);

FIG. 3 shows a summary of XRD patterns of EA_{0.2}MA_{0.8}SnₓPb₁₋ₓI₃ for different Sn percentages (FIG. 3A) and zoomed inset for the main diffraction peak at 14° 2θ (FIG. 3B);

FIG. 4 shows shaded maps of tolerance factor values as a function of A₂ and Sn percentages;

FIGS. 5A and 5B show XRD patterns for Pb-based (black) and Pb/Sn (grey) based compositions for the different cations;

FIGS. 6A and 6B shows absorption spectra for Pb (solid line) and Pb/Sn (dashed line) based compositions for the different cations;

FIG. 7 shows energy bandgap values for Pb—and Pb/Sn-based compositions for different cations (from Table 3);

FIG. 8 shows SEM images for Pb and Pb/Sn compositions for different cation combinations (according to cations in Table 3);

FIG. 9 shows the current-voltage plot for the optimal devices employing perovskites according to Table 4 as absorbers.

FIG. 10 shows the layered XRD patterns for Pb and Pb/Sn composition for different cations according to those in Table 3.

FIG. 11 illustrates the SEM images of the Pb/Sn compositions for different cation combinations according to those in Table 3, with and without the presence of SnF₂.

FIG. 12A, 12B, 12C and 12D shows the device characteristics, for PCE %, V_{oc}, J_{SC}, and FF, respectively, for PbSn compositions with different cation combinations according to Table 4, with and without the presence of SnF₂.

FIG. 13A shows a summary plot of the change in the main (100) XRD peak for Pb/Sn composition of different A cations according to Table 3 with and without SnF₂ under humidity exposure for 0 hours, 24 hours and 48 hours.

FIG. 13B shows a summary plot of the change in the main (100) XRD peak for Pb/Sn composition of different A cations according to Table 3 with and without SnF₂ under thermal exposure for 0 hours, 24 hours and 48 hours.

FIG. 14 illustrates the varying tolerance factor, T, of a 60% Sn-based triple cation perovskite, with different % compositions of cations according to Table 1 against MA and Cs.

FIGS. 15A and 15B show the XRD of 60% Sn-based triple cation perovskite compositions with different % compositions of cations according to Table 5. FIG. 15B shows a close up XRD from to 15° 20.

FIG. 16 shows a plot of the effective A-cation radius R_{A} and the main perovskite peak position against the compositions listed in Table 5.

FIG. 17 shows a close-up XRD in the range of 6 to 15° for the compositions listed in Table 5 at different annealing temperatures of 100° C. (solid line) and 120° C. (dashed line).

FIGS. 18A and 18B show the XRDs of 60% Sn-based triple cation perovskite compositions with trace amounts of Cs added according to Table 6. FIG. 18B shows a close up XRD from 12 to 15° 20.

FIG. 19 shows the % change in the intensity of the perovskite peak at ˜14° (observed in FIG. 18B), upon the addition of different trace amounts of Cs according to Table 6.

### DETAILED DESCRIPTION OF INVENTION

### Definitions

The term “photoactive”, as used herein, refers to a region, layer or material that is capable of responding to light photoelectrically. A photoactive region, layer or material is therefore capable of absorbing the energy carried by photons in light that then results in the generation of electricity (e.g. by generating either electron-hole pairs or excitons).

The term “perovskite”, as used herein, refers to a material with a three-dimensional crystal structure related to that of CaTiO₃ or a material comprising a layer of material, which layer has a structure related to that of CaTiO₃. The structure of CaTiO₃ can be represented by the formula ABX₃, wherein A and B are cations of different sizes and X is an anion. In the unit cell, the A cations are at (0,0,0), the B cations are at (½, ½, ½) and the X anions are at (½, ½, 0). The A cation is usually larger than the B cation. The skilled person will appreciate that when A, B and X are varied, the different ion sizes may cause the structure of the perovskite material to distort away from the structure adopted by CaTiO₃ to a lower-symmetry distorted structure. The symmetry will also be lower if the material comprises a layer that has a structure related to that of CaTiO₃. Materials comprising a layer of perovskite material are well known. For instance, the structure of materials adopting the K₂NiF₄ type structure comprises a layer of perovskite material. The skilled person will appreciate that a perovskite material can be represented by the formula [A][B][X]₃, wherein [A] is at least one cation, [B] is at least one cation and [X] is at least one anion.

When the perovskite comprises more than one A cation, the different A cations may be distributed over the A sites in an ordered or disordered way. When the perovskite comprises more than one B cation, the different B cations may be distributed over the B sites in an ordered or disordered way. When the perovskite comprises more than one X anion, the different X anions may be distributed over the X sites in an ordered or disordered way. The symmetry of a perovskite comprising more than one A cation, more than one B cation or more than one X cation, will often be lower than that of CaTiO₃.

As mentioned in the preceding paragraph, the term “perovskite”, as used herein, refers to (a) a material with a three-dimensional crystal structure related to that of CaTiO₃, (b) a material comprising a layer of material, wherein the layer has a structure related to that of CaTiO₃ or (c) a material with some hexagonal perovskite symmetry which maintains the ABX₃ stoichiometry, but wherein some of the B-cation octahedra may share opposite faces, forming chains along the c-axis, meanwhile some of the B-cation octahedra may be corner shared. Although these categories of perovskite may be used in the devices according to the invention, it is preferable in some circumstances to use a perovskite of the first category, (a), i.e. a perovskite having a three-dimensional (3D) crystal structure. Such perovskites typically comprise a 3D network of perovskite unit cells without any separation between layers. Perovskites of the second category, (b), on the other hand, include perovskites having a two-dimensional (2D) layered structure.

Perovskites having a 2D layered structure may comprise layers of perovskite unit cells that are separated by (intercalated) molecules; an example of such a 2D layered perovskite is [2-(1-cyclohexenyl)ethylammonium]₂PbBr₄. 2D layered perovskites tend to have high exciton binding energies, which favours the generation of bound electron-hole pairs (excitons), rather than free charge carriers, under photoexcitation. The bound electron-hole pairs may not be sufficiently mobile to reach the p-type or n-type contact where they can then transfer (ionise) and generate free charge. Consequently, in order to generate free charge, the exciton binding energy has to be overcome, which represents an energetic cost to the charge generation process and results in a lower voltage in a photovoltaic cell and a lower efficiency. Perovskites of the third category, (c), include perovskites which may have some stacks of one-dimensional (1D) face-sharing across the c-axis, along with some 3D perovskite character. In contrast, perovskites having a fully 3D crystal structure tend to have much lower exciton binding energies (on the order of thermal energy) and can therefore generate free carriers directly following photoexcitation. Accordingly, the perovskite semiconductor employed in the devices and processes of the invention is preferably a perovskite of the first category, (a), i.e. a perovskite which has a three-dimensional crystal structure. This is particularly preferable when the optoelectronic device is a photovoltaic device.

The perovskite material employed in the present invention is one which is capable of absorbing light and thereby generating free charge carriers. Thus, the perovskite employed is a light-absorbing perovskite material. However, the skilled person will appreciate that the perovskite material could also be a perovskite material that is capable of emitting light, by accepting charge, both electrons and holes, which subsequently recombine and emit light. Thus, the perovskite employed may be a light-emitting perovskite.

As the skilled person will appreciate, the perovskite material employed in the present invention may be a perovskite which acts as an n-type, electron-transporting semiconductor when photo-doped. Alternatively, it may be a perovskite which acts as a p-type hole-transporting semiconductor when photo-doped. Thus, the perovskite may be n-type or p-type, or it may be an intrinsic semiconductor. In preferred embodiments, the perovskite employed is one which acts as an n-type, electron-transporting semiconductor when photo-doped. The perovskite material may exhibit ambipolar charge transport, and therefore act as both n-type and p-type semiconductor. In particular, the perovskite may act as both n-type and p-type semiconductor depending upon the type of junction formed between the perovskite and an adjacent material.

Typically, the perovskite semiconductor used in the present invention is a photosensitizing material, i.e. a material which is capable of performing both photogeneration and charge transportation.

The term “mixed-anion”, as used herein, refers to a compound comprising at least two different anions. The term “halide” refers to an anion of an element selected from Group 17 of the Periodic Table of the Elements, i.e., a halogen. Typically, halide anion refers to a fluoride anion, a chloride anion, a bromide anion or an iodide anion.

The term “metal halide perovskite”, as used herein, refers to a perovskite, the formula of which contains at least one metal cation and at least one halide anion. The term “organometal halide perovskite”, as used herein, refers to a metal halide perovskite, the formula of which contains at least one organic cation.

The term “organic material” takes its normal meaning in the art. Typically, an organic material refers to a material comprising one or more compounds that comprise a carbon atom. As the skilled person would understand it, an organic compound may comprise a carbon atom covalently bonded to another carbon atom, or to a hydrogen atom, or to a halogen atom, or to a chalcogen atom (for instance an oxygen atom, a sulphur atom, a selenium atom, or a tellurium atom). The skilled person will understand that the term “organic compound” does not typically include compounds that are predominantly ionic such as carbides, for instance.

The term “organic cation” refers to a cation comprising carbon. The cation may comprise further elements, for example, the cation may comprise hydrogen, nitrogen or oxygen. The term “inorganic cation” refers to a cation that is not an organic cation. By default, the term “inorganic cation” refers to a cation that does not contain carbon.

The term “semiconductor”, as used herein, refers to a material with electrical conductivity intermediate in magnitude between that of a conductor and a dielectric. A semiconductor may be an n-type semiconductor, a p-type semiconductor or an intrinsic semiconductor.

The term “dielectric”, as used herein, refers to material which is an electrical insulator or a very poor conductor of electric current. The term dielectric therefore excludes semiconducting materials such as titania. The term dielectric, as used herein, typically refers to materials having a band gap of equal to or greater than 4.0 eV. (The band gap of titania is about 3.2 eV.) The term “n-type”, as used herein, refers to a region, layer or material that comprises an extrinsic semiconductor with a larger concentration of electrons than holes. In n-type semiconductors, electrons are therefore majority carriers and holes are the minority carriers, and they are therefore electron transporting materials. The term “n-type region”, as used herein, therefore refers to a region of one or more electron transporting (i.e. n-type) materials. Similarly, the term “n-type layer” refers to a layer of an electron-transporting (i.e. an n-type) material. An electron-transporting (i.e. an n-type) material could be a single electron-transporting compound or elemental material, or a mixture of two or more electron-transporting compounds or elemental materials. An electron-transporting compound or elemental material may be undoped or doped with one or more dopant elements.

The term “p-type”, as used herein, refers to a region, layer or material that comprises an extrinsic semiconductor with a larger concentration of holes than electrons. In p-type semiconductors, holes are the majority carriers and electrons are the minority carriers, and they are therefore hole transporting materials. The term “p-type region”, as used herein, therefore refers to a region of one or more hole transporting (i.e. p-type) materials. Similarly, the term “p-type layer” refers to a layer of a hole-transporting (i.e. a p-type) material. A hole-transporting (i.e. a p-type) material could be a single hole-transporting compound or elemental material, or a mixture of two or more hole-transporting compounds or elemental materials. A hole-transporting compound or elemental material may be undoped or doped with one or more dopant elements.

The term “band gap”, as used herein, refers to the energy difference between the top of the valence band and the bottom of the conduction band in a material. The skilled person may readily measure the band gap of a material without undue experimentation.

The term “layer”, as used herein, refers to any structure which is substantially laminar in form (for instance extending substantially in two perpendicular directions, but limited in its extension in the third perpendicular direction). A layer may have a thickness which varies over the extent of the layer. Typically, a layer has approximately constant thickness. The “thickness” of a layer, as used herein, refers to the average thickness of a layer. The thickness of layers may easily be measured, for instance by using microscopy, such as electron microscopy of a cross section of a film, or by surface profilometry for instance using a stylus profilometer.

The term “porous”, as used herein, refers to a material within which pores are arranged. Thus, for instance, in a porous material the pores are volumes within the body of the material where there is no material. The individual pores may be the same size or different sizes. The size of the pores is defined as the “pore size”. The limiting size of a pore, for most phenomena in which porous solids are involved, is that of its smallest dimension which, in the absence of any further precision, is referred to as the width of the pore (i.e. the width of a slit-shaped pore, the diameter of a cylindrical or spherical pore, etc.). To avoid a misleading change in scale when comparing cylindrical and slit-shaped pores, one should use the diameter of a cylindrical pore (rather than its length) as its “pore-width” (Rouquerol, J. et al., (1994) Recommendations for the characterization of porous solids (Technical Report). Pure and Applied Chemistry, 66(8)). The following distinctions and definitions were adopted in previous IUPAC documents (J. Haber. (1991) Manual on catalyst characterization (Recommendations 1991). Pure and Applied Chemistry.): micropores have widths (i.e. pore sizes) smaller than 2 nm; mesopores have widths (i.e. pore sizes) of from 2 nm to 50 nm; and macropores have widths (i.e. pore sizes) of greater than 50 nm. In addition, nanopores may be considered to have widths (i.e. pore sizes) of less than 1 nm.

Pores in a material may include “closed” pores as well as open pores. A closed pore is a pore in a material which is a non-connected cavity, i.e. a pore which is isolated within the material and not connected to any other pore and which cannot therefore be accessed by a fluid to which the material is exposed. An “open pore” on the other hand, would be accessible by such a fluid. The concepts of open and closed porosity are discussed in detail in J. Rouquerol et al.

Open porosity, therefore, refers to the fraction of the total volume of the porous material in which fluid flow could effectively take place. It therefore excludes closed pores. The term “open porosity” is interchangeable with the terms “connected porosity” and “effective porosity”, and in the art is commonly reduced simply to “porosity”. The term “without open porosity”, as used herein, therefore refers to a material with no effective porosity. Thus, a material without open porosity typically has no macropores and no mesopores. A material without open porosity may comprise micropores and nanopores, however. Such micropores and nanopores are typically too small to have a negative effect on a material for which low porosity is desired.

In addition, polycrystalline materials are solids that are composed of a number of separate crystallites or grains, with grain boundaries at the interface between any two crystallites or grains in the material. A polycrystalline material can therefore have both interparticle/interstitial porosity and intraparticle/internal porosity. The terms “interparticle porosity” and “interstitial porosity”, as used herein, refer to pores between the crystallites or grains of the polycrystalline material (i.e. the grain boundaries), whilst the terms “intraparticle porosity” and “internal porosity”, as used herein, refer to pores within the individual crystallites or grains of the polycrystalline material. In contrast, a single crystal or monocrystalline material is a solid in which the crystal lattice is continuous and unbroken throughout the volume of the material, such that there are no grain boundaries and no interparticle/interstitial porosity.

The term “compact layer”, as used herein, refers to a layer without mesoporosity or macroporosity. A compact layer may sometimes have microporosity or nanoporosity.

The term “scaffold material”, as used herein, therefore refers to a material that is capable of acting as a support for a further material. The term “porous scaffold material”, as used herein, therefore refers to a material which is itself porous, and which is capable of acting as a support for a further material.

The term “transparent”, as used herein, refers to a material or object which allows light to pass through almost undisturbed so that objects behind can be distinctly seen. The term “semi-transparent”, as used herein, therefore refers to a material or object which has a transmission (alternatively and equivalently referred to as a transmittance) to light intermediate between a transparent material or object and an opaque material or object. Typically, a transparent material will have an average transmission for light of around 100%, or from 90 to 100%. Typically, an opaque material will have an average transmission for light of around 0%, or from 0 to 5%. A semi-transparent material or object will typically have an average transmission for light of from to 90%, typically 40 to 60%. Unlike many translucent objects, semi-transparent objects do not typically distort or blur images. Transmission for light may be measured using routine methods, for instance by comparing the intensity of the incident light with the intensity of the transmitted light.

The term “electrode”, as used herein, refers to a conductive material or object through which electric current enters or leaves an object, substance, or region. The term “negative electrode”, as used herein, refers to an electrode through which electrons leave a material or object (i.e. an electron collecting electrode). A negative electrode is typically referred to as an “anode”. The term “positive electrode”, as used herein, refers to an electrode through which holes leave a material or object (i.e. a hole collecting electrode). A positive electrode is typically referred to as a “cathode”. Within a photovoltaic device, electrons flow from the positive electrode/cathode to the negative electrode/anode, whilst holes flow from the negative electrode/anode to the positive electrode/cathode.

The term “front electrode”, as used herein, refers to the electrode provided on that side or surface of a photovoltaic device that it is intended will be exposed to sun light. The front electrode is therefore typically required to be transparent or semi-transparent so as to allow light to pass through the electrode to the photoactive layers provided beneath the front electrode. The term “back electrode”, as used herein, therefore refers to the electrode provided on that side or surface of a photovoltaic device that is opposite to the side or surface that it is intended will be exposed to sunlight.

The term “charge transporter” refers to a region, layer or material through which a charge carrier (i.e. a particle carrying an electric charge), is free to move. In semiconductors, electrons act as mobile negative charge carriers and holes act as mobile positive charges. The term “electron transporter” therefore refers to a region, layer or material through which electrons can easily flow and that will typically reflect holes (a hole being the absence of an electron that is regarded as a mobile carrier of positive charge in a semiconductor). Conversely, the term “hole transporter” refers to a region, layer or material through which holes can easily flow and that will typically reflect electrons.

The term “consisting essentially of” refers to a composition comprising the components of which it consists essentially as well as other components, provided that the other components do not materially affect the essential characteristics of the composition. Typically, a composition consisting essentially of certain components will comprise greater than or equal to 95 wt % of those components or greater than or equal to 99 wt % of those components.

The term “roughness”, as used herein, refers to the texture of a surface or edge and the extent to which it is uneven or irregular (and therefore lacks smoothness or regularity). The roughness of a surface can be quantified by any measure of the deviations of the surface in a direction that is typically normal to the average surface. As a measure of roughness, the roughness average or mean roughness (Rₐ) is the arithmetical mean of the absolute values of all deviations from a straight line within a specified reference or sampling length of the surface profile. As an alternative measure of roughness, the root mean square roughness (Rᵣₘₛ or R_{q}) is the root mean square of the values of all deviations from a straight line within a specified reference or sampling length of the surface profile.

The term “conform”, as used herein, refers to an object that is substantially the same in form or shape as an another object. A “conformal layer”, as used herein, therefore refers to a layer of material that conforms to the contours of the surface on which the layer is formed. In other words, the morphology of the layer is such that the thickness of the layer is approximately constant across the majority of the interface between the layer and the surface on which the layer is formed.

In order to form a material with a perovskite crystal structure, the organic cations of an organic-inorganic hybrid perovskite must have suitable dimensions so as not to distort the lattice to such an extent that alternative structures are more energetically favourable.

Goldschmidt tolerance factor (t) is an empirical index for predicting stable crystal structures of perovskite materials. A t value between 0.91 and 1.0 is favourable for a cubic perovskite structure, meanwhile between a t value between 0.71 to 0.9 produces perovskite structures with tilted octahedra such as orthorhombic or rhombohedral. Furthermore, a larger tolerance factor, (t>1) usually results in the formation of hexagonal perovskite structures, while smaller values of tolerance factor (t<0.71) usually result in distortions of the perovskite leading to different structures, typically not perovskite crystalline forms. CH(NH₂)2PbI₃ (FAPbI₃) can exist in the perovskite a-phase (black phase) with good photovoltaic properties. However, it has a large tolerance factor and is more stable in the 2H hexagonal perovskite or delta-2H-phase (also known as yellow phase due to its colour), with δ-to-a phase-transition temperature higher than room temperature. On the other hand, CsPbI₃ is stabilized to an orthorhombic structure (50-phase) at room temperature due to its small tolerance factor.

Until now, only perovskites having formamidinium (FA) or methyl ammonium (MA) organic cations have been successfully fabricated and studied in devices, often with the addition of small Cs or Rb cations to reduce lattice strain and enable a perovskite crystal structure to be achieved. Other larger organic cations such as ethyl ammonium (EA), imidazolium, guanidinium, dimethyl ammonium etc. have been provided in lists of alternative cations to FA and MA but have not been shown to form materials having a stable perovskite crystal structure because of the unfavourable tolerance factor. For example, Yongping Fu, Matthew P. Hautzinger et al. (ACS Cent. Sci. 2019, 5, 8, 1377-1386) recently remarked “Large organic cations, such as dimethylammonium (DMA), ethylammonium (EA), guanidinium (GA), and acetamidinium (Ac), do not support a 3D perovskite structure.”

The present inventors have discovered that by mixing Pb and Sn in the same crystal lattice, it becomes possible to incorporate these larger organic cations to produce a material having a relatively stable 3D perovskite crystal structure.

### Perovskite Material

In one aspect of the invention is disclosed a perovskite material having the formula (I):

AₐA′_{b}A″_{c}Sn_{(y)}Pb_{(1-y)}X₃ (I)
wherein A consists of a monovalent cation;
A′ consists of a monovalent organic cation having an ionic radius greater than 2.53 Å;
A″ consists of a monovalent inorganic cation;
X comprises one or more halide anions;
0<a<1;
0<b<1;
0≤c<1;
a+b+c=1; and
0<y<1.

In an embodiment, A′ is a monovalent organic cation having an ionic radius greater than 2.53 Å.

The A′ cation should have a radius greater than that of the Formamidinium ion, i.e. it should be greater than 2.53 Å. Preferably, A′ is an ammonium-based monovalent organic cation. The respective ionic radii sizes of ammonium-based cations can be extracted from the standard method adopted by Kieslich et al. (“Solid-state principles applied to organic-inorganic perovskites: new tricks for an old dog”, Chem. Sci. 2014, 5, 4712-4715), wherein the radius of the A cation, r_{A} is worked out according to the formula:

r_{A}=rₘₐₛₛ+rᵢₒₙ

wherein rₘₐₛₛ is the distance between the centre of mass of the molecule and the atom with the largest distance to the centre of mass (excluding H atoms) and rᵢₒₙ is the corresponding ionic radius of this atom. Further, in order to calculate the radius of A cations consistently, rₘₐₛₛ and rᵢₒₙ are derived from crystallographic data and the ions are assumed to be rigid spheres with free rotational freedom around the centre of mass.

Table 1 below provides some suitable A′ cations for use in this invention:

TABLE 1
Alternative organic cations and their corresponding ionic radii

| A cation | Ionic radius (A) |
|---|---|
| Imidazolium (Im) | 2.58 |
| Dimethylammonium (Dm) | 2.72 |
| Ethylammonium | 2.74 |
| Acetamidinium (Ac) | 2.77 |
| Guanidinium (Gua) | 2.78 |
| Tetramethylammonium (TMA) | 2.92 |
| Thiazolium (TM) | 3.20 |
| Tropylium (TP) | 3.33 |

Suitable organic cations and their respective radii can also be found in Cheetham et al., Chem. Sci., 2015, 6, 3430 and Travis et al., Chem. Sci., 2016, 7, 4548-4556.

The tolerance factor T is used as a tool to predict whether a perovskite structure (represented for instance by the general formula ABX₃) will be formed for a specific combination of elements. It is defined by the following formula:

$$τ = \frac{{r}_{A , eff} + {r}_{X}}{\sqrt{2} ( {r}_{B} + {r}_{X} )}$$

where r_{Aeff}is the effective radius of the multiple A cations according to the formula:

$${r}_{A , eff} = a * {r}_{A} + b * {r}_{{A}^{′}} + c * {r}_{{A}^{″}} = a * {r}_{A} + {r}_{{effAA}^{′} {A}^{″}}$$

and where r_{B} and r_{X} are the effective ionic radii of the B and X-site respectively and can be calculated by modifying the formula above.

Empirically, a τ value between 0.71 and 1 indicates that perovskites do form, with the ideal cubic structure to be obtained for τ=1. Values lower than 0.71 or larger than 1 imply that the A-cation is too small or too large to fit in the cavity, respectively. Tolerance factor calculations have been utilized to assess the geometrical compatibility of the described families with a perovskite structure for all combinations.

Kieslich et al. (“An extended Tolerance Factor approach for organic-inorganic perovskites”, Chem. Sci. 2015, 6, 3430-3433) provide data on the tolerance factor of ammonium ions with metal halides in Table 1 of the supplementary information. The tolerance factor of the material increases as the ionic radius of the ammonium cation increases. It is shown that for tin bromides the tolerance factor of the selected A cations of Table 1 herein start from 1.049 Å for the smallest A cation (imidazolium) and reaches 1.203 Å for the largest (tropylium). Meanwhile for tin iodides, the tolerance factor is from 1.032 Å to 1.167 Å. With respect to lead, the tolerance factor of the cations in Table 1 varies from 1.019 Å to 1.212 Å for bromides and from 0.997 to 1.153 for iodides.

Thus, by optimising the amount and identity of the A cations and X anions in combination with mixed Pb and Sn components, the tolerance factor of materials according to the present invention can be favourably manipulated to yield a stable perovskite structure.

In a preferred embodiment, A′ is a monovalent organic cation selected from the group consisting of: ethyl ammonium (EA), imidazolium (Im), guanidinium (Gua), dimethyl ammonium (DMA), and acetamidinium (Ac), tetramethylammonium (TMA), thiazolium (TM), tropylium (TP). Preferably, A′ is an ethyl ammonium (EA) or a dimethylammonium cation. Most preferably, A′ is an ethyl ammonium (EA) cation.

In a preferred embodiment, A′ is used in sufficient quantity such that it is not acting as a passivating agent. It is commonly known in the field of photovoltaics that passivating agents include the use of additional materials or processes to passivate defects in materials. Thus, the aim of using a passivating agent is not to form a new composition but to improve the properties of an existing one. Passivating agents are generally added as an excess and do not intercalate into the perovskite structure. In the present invention, on the other hand, the large cation A′ is intentionally substituted into and becomes part of the perovskite structure. Substitutions can change the composition of the material.

Sometimes, in the prior art, authors may claim that in passivating, the additional component becomes part of the structure, but this is generally not intentional nor proven, and it is not known how much (if any at all) actually enters into the structural lattice.

In an embodiment, preferably, 0.03<b<1, more preferably 0.05<b<1, even more preferably 0.1<b<1, further preferably 0.15<b<0.5, and even further preferably 0.15<b s 0.4. In this embodiment, A may be a monovalent organic cation such as those listed below.

A consists of a cation different from A′. In one embodiment, A preferably is a monovalent organic cation. Typically, A is an organic cation selected from methylammonium (MA, CH₃NH₃⁺), formamidinium (FA; HC(NH)₂)₂⁺) and ethyl ammonium (EA; CH₃CH₂NH₃⁺). In one embodiment, A consists of an organic cation selected from FA and MA. Most preferably, A is MA.

The value of y may be from 0 to 1. Preferably, y is more than 0.2 and less than 0.7, or more than 0.25 and less than 0.65. Most preferably, y is around 0.6.

Preferably, A″, when present, is an inorganic cation selected from Cs⁺, Rb⁺, Cu⁺, Pd⁺, Pt⁺, Ag⁺, Au⁺, Rh⁺ and Ru⁺. Preferably, A″ consists of an inorganic cation selected from Cs⁺ and Rb⁺. Most preferably, A″ is Cs⁺.

In a preferred embodiment, A′ is an EA cation and A is an MA cation. When A′ is an EA cation, A does not consist of an EA cation, since A and A′ are different.

X comprises a halide anion. X comprises one or more halide anions selected from fluoride, chloride, bromide, and iodide. Each different X anion in the perovskite structure may be the same or different. Preferably, X comprises one or more halide anions selected from bromide and iodide.

In some examples, X preferably comprises two different halide anions selected from fluoride, chloride, bromide, and iodide, and preferably selected from chloride, bromide and iodide. More preferably, the halide anions in the perovskite, X, comprises bromide and iodide.

In a preferred embodiment, c is zero, i.e. the perovskite is a double cation perovskite. The formula may be as follows:

A₍ₓ₎A′₍₁₋ₓ₎Sn_{(y)}Pb_{(1-y)}X₃ wherein 0<x<1 and 0<y<1.

The definitions of A, A′ and X are as outlined above. Typically, 0.03<x<1, preferably 0.05<x<1, more preferably 0.1<x<1. Preferably, x is more than 0.1 and less than 0.6, or more than 0.1 and less than 0.3. Most preferably, x is around 0.2.

The value of y may be from 0 to 1. Preferably, y is more than 0.2 and less than 0.7, or more than 0.25 and less than 0.65. Most preferably, y is around 0.6.

Particularly preferred perovskites have formulae: A′ₓMA₁₋ₓSn_{y}Pb_{1-y}I₃ wherein 0<x<1 and 0<y<1. Typically 0.1<x<1.

In an embodiment of the invention, the perovskite material has the formula EA₍ₓ₎MA₍₁₋ₓ₎Sn_{(y)}Pb_{(1-y)}X₃ wherein x and y are as defined above, In a further preferred embodiment, the perovskite material has the formula EA₍ₓ₎MA₍₁₋ₓ₎Sn_{(y)}Pb_{(1-y)}I₃ where the values of x and y are as defined above.

In another embodiment of the invention, the perovskite composition may be a triple cation perovskite in accordance with the above formula, AₐA′_{b}A″_{c}Sn_{(y)}Pb_{(1-y)}X₃, wherein A, A′ and A″ are as defined above, c is >0 and is equal to 1-a-b and 0<b<1 and 0<a<1.

In perovskites comprising three cations, typically 0.03<b<1, preferably 0.05<b<1, more preferably 0.1<b<1, even more preferably 0.15<b<0.5, further preferably in which 0.15<b≤0.4. Preferably, A″ is Cs⁺ and A is MA, such that a preferred formula for the triple cation perovskite is, MAₐA′_{b}Cs_{1-a-b}Sn_{y}Pb_{1-y}X₃ wherein 0<a<1, 0<b<1, and 0<c<1. X is selected from one or more halide anions. Preferably X is I.

For these triple cation compositions, preferably 0.5≤y≤0.7. In this case τ˜1 can be achieved by varying the ratios between the three different cations. In general, the greater the proportion of Cs in the lattice, which is a smaller cation, the more A′ (larger cation) that can be added. We have found that for a Cs proportion up to 30% and a suitable A′/MA ratio, τ=1 can be achieved. Regarding the A′ proportion, a value in the range 50-60% is preferred in order to reach ideal tolerance factor values. More Cs will lower the T value below 1, while a higher A′ content will lead to values over 1.

Preferred perovskites of the invention have formulae AₐA′_{b}A″_{c}Pb_{y}Sn_{(1-y)}I₃ and AₓA′₍₁₋ₓ₎Pb_{y}Sn_{(1-y)}I₃, wherein A is MA, A′ is a monovalent organic cation having radius >2.53 Å and A″, if present, is selected from Cs⁺ and Rb⁺;

In these preferred perovskites,
0<a<1;
0<b<1, preferably 0.1<b<1;
0≤c<1;
a+b+c=1; and
0<x<1 and 0<y<1.

In another embodiment is a perovskite material having the formula (I):

AₐA′_{b}A″_{c}Sn_{(y)}>Pb_{(1-y)}X₃ (I)
wherein A comprises a monovalent cation
A′ comprises a monovalent organic cation having an ionic radius greater than 2.53 Å;
A″ comprises a monovalent inorganic cation;
X comprises a halide anion;
0<a<1;
0<b<1;
0≤c<1;
a+b+c=1; and
0<y<1.

In a third aspect of the invention is disclosed a semiconductor device having a photoactive region comprising a metal halide perovskite material according to the first or second aspects of the invention. In an embodiment of the invention, the semiconductor is a photovoltaic device having a photoactive region.

In a further embodiment of the invention, the photoactive region of the photovoltaic device comprises a thin film of the perovskite material, the thickness of the thin film of the perovskite material typically being in the range 50 nm to 2000 nm, preferably being in the range from 100 nm to 1500 nm.

In an embodiment, the photoactive region comprises an n-type region, comprising at least one n-type layer, and a layer of the perovskite material in contact with the n-type region.

In a further embodiment, the photoactive region comprises: an n-type region comprising at least one n-type layer; a p-type region comprising at least one p-type layer; and a layer of the perovskite material disposed between the n-type region and the p-type region.

Preferably the photoactive layer is a compact layer without open porosity.

In a fourth aspect of the invention is disclosed a multijunction photovoltaic device comprising two or more sub-cells, the first sub cell comprising a photovoltaic device according to the third aspect of the invention, and a further sub-cell comprising a photoactive layer having a bandgap of between 1.5 and 2.0 eV, or 1.55 and 1.95 eV or 1.6 and 1.9 eV. Preferably the bandgap of the photoactive region of the further sub-cell is between 1.5 and 1.9 eV and is preferably in the range 1.6 to 1.9 eV.

The present inventors have found such perovskite materials can have bandgaps in the region from 1.3 eV to 1.65 eV and that layers of such perovskite materials can be readily formed with suitable crystalline morphologies and phases. Band gaps are calculated using UV-VIS and Tauc Plot analysis. In particular, the inventors have developed a photoactive perovskite material for use in the bottom sub-cell in an all-perovskite tandem photovoltaic device in combination with a wider bandgap perovskite top sub-cell. The material could alternatively be used in a single junction device, or as the middle junction (when the band gap is around 1.40-1.45 eV) in a multi-junction device, such as, for example, a perovskite-perovskite-Si, perovskite-perovskite-CIGS or all-perovskite triple junction device.

The present invention provides a novel perovskite material of high crystallinity. The low band gap of this perovskite permits its use not only in single-junction devices but also in all perovskite tandem configurations, greatly boosting the significance of this new material.

The present inventors have surprisingly found that the introduction of a suitably sized cation, for instance, the EA cation into mixed Pb/Sn perovskites assists in creating high texturing and orientation within the material, advantageously stabilising the crystal structure whilst providing an advantageous bandgap.

In a typical multi-junction device, the top photoactive region/sub-cell in the stack has the highest bandgap, with the bandgap of the lower photoactive regions/sub-cells reducing towards the bottom of the device. This arrangement maximizes photon energy extraction as the top photoactive region/sub-cell absorbs the highest energy photons first whilst allowing the transmission of photons with less energy. Each subsequent photoactive region/sub-cell then extracts energy from photons closest to its bandgap thereby minimizing thermalization losses.

The bottom photoactive region/sub-cell then absorbs all remaining photons with energy above its bandgap. When designing multi-junction cells, it is therefore important to choose photoactive regions/sub-cells with the right bandgaps in order to optimise harvesting of the solar spectrum. In this regard, for a tandem photovoltaic device that comprises two photoactive regions/sub-cells, a top photoactive region/sub-cell and a bottom photoactive region/sub-cell, it has been shown that the bottom photoactive region/sub-cell should have a bandgap of around 1.1 eV whilst the top photoactive region/sub-cell should have a bandgap of around 1.7 eV (Coutts, T et al., (2002) “Modelled performance of polycrystalline thin-film tandem solar cells”, Progress in Photovoltaics: Research and Applications, 10(3), pp. 195-203).

There is a continued need for high quality materials with a band gap in the region of 1.3-1.45 eV for use in single-junction devices and for the middle junction in triple junction solar cells mentioned above. In the prior art there are some Pb/Sn 1.34 eV materials disclosed, but these have poor crystallinity and low device efficiencies. Surprisingly, no 1.40-1.45 eV materials are known with sufficient quality for practical photovoltaic devices. The present invention fills this previously inaccessible band gap energy range.

Photovoltaic device The perovskite material of the present invention may be used in a semiconductor device, preferably a photovoltaic device. The perovskite material is advantageously configured to function as a light absorber/photosensitiser within the photoactive region of a photovoltaic device. The photoactive region may comprise a thin film of the perovskite material, and preferably the thickness of the thin film of the perovskite material is typically from 50 nm to 2000 nm, preferably from 100 nm to 1500 nm, and more preferably from 400 nm to 1200 nm, and yet more preferably from 600 nm to 1000 nm.

The photoactive region may comprise an n-type region comprising at least one n-type layer, and a layer of the perovskite material in contact with the n-type region.

The photoactive region may comprise an n-type region comprising at least one n-type layer, a p-type region comprising at least one p-type layer; and a layer of the perovskite material disposed between the n-type region and the p-type region.

The photoactive region may comprise a layer of the perovskite material without open porosity. The layer of perovskite material may then form a planar heterojunction with one or both of the n-type region and the p-type region.

Alternatively, although less preferably, the layer of the perovskite material may be in contact with a porous scaffold material that is disposed between the n-type region and the p-type region. The porous scaffold material may comprise or consist essentially of any of a dielectric material and a semiconducting/charge transporting material. The layer of the perovskite material may then be disposed within the pores of the porous scaffold material, or in other words, be conformal with a surface of the porous scaffold material. Alternatively, the layer of the perovskite material may fill the pores of the porous scaffold material and form a capping layer on the porous scaffold material, wherein the capping layer consists of a layer of the photoactive material without open porosity.

The photovoltaic device may further comprise a first electrode and a second electrode, with the photoactive region being disposed between the first and second electrodes, wherein the first electrode is in contact with the n-type region of the photoactive region and the second electrode is in contact with the p-type region of the photoactive region. The first and second electrode may then comprise a transparent or light transmissive electrically conductive material and the second electrode may comprise a metal or a second light transmissive electrically conductive material.

The first electrode may then be an electron collecting electrode, whilst the second electrode is a hole collecting electrode.

The photovoltaic device may further comprise a first electrode and a second electrode, with the photoactive region being disposed between the first and second electrodes, wherein the first electrode is in contact with the p-type region of the photoactive region and the second electrode is in contact with the n-type region of the photoactive region. The first electrode may then comprise a transparent or light transmissive electrically conductive material, and the second electrode may comprise a metal or a second light transmissive electrically conductive material. The first electrode may then be a hole collecting electrode, whilst the second electrode is an electron collecting electrode.

The photovoltaic device may have a multi-junction structure comprising a first sub-cell disposed over a second sub-cell, the first sub-cell comprising the photoactive region comprising the perovskite material. The photovoltaic device may then have a monolithically integrated structure.

In a monolithically integrated multi-junction photovoltaic device the two or more photovoltaic sub-cells are deposited directly onto one another and are therefore electrically connected in series.

The photovoltaic device may then further comprise an intermediate region connecting the first sub-cell to the second sub-cell, wherein each intermediate region comprises one or more interconnect layers.

The photovoltaic device having a multi-junction structure may further comprise a first electrode, a second electrode, with the first sub-cell and the second sub-cell disposed between the first and second electrodes.

The first electrode may then be in contact with the p-type region of the first sub-cell, and wherein the first electrode comprises a transparent or semi-transparent electrically conductive material.

The first electrode may then be a hole collecting electrode, whilst the second electrode is an electron collecting electrode. In a tandem device, the second electrode will then be in contact with the second sub-cell.

Alternatively, the first electrode may be in contact with the n-type region of the first sub-cell, and wherein the first electrode comprises a transparent or semi-transparent electrically conductive material. The first electrode may then be an electron collecting electrode, whilst the second electrode is a hole collecting electrode. In a tandem device, the second electrode will then be in contact with the second sub-cell.

When the photovoltaic device has a multi-junction structure the second sub-cell of the photovoltaic device may comprise any of a second perovskite material, crystalline silicon, CdTe, CuZnSnSSe, CuZnSnS, or CuInGaSe (CIGS).

As an alternative, the multijunction solar cell can comprise three sub cells, the top cell being a perovskite cell having a band gap in the range 1.5 to 1.9 eV, the middle sub cell having a perovskite layer according to the present invention, and the bottom sub cell comprising a sub cell having an energy band gap in the range 1.1 to 1.3 eV, such as for example crystalline silicon, a narrow band gap perovskite layer or CIGS.

The perovskite layer may be prepared as described in WO2013/171517, WO2014/045021, WO2016/198889, WO2016/005758, WO2017/089819, and in the reference books “Photovoltaic Solar Energy: From Fundamentals to Applications” edited by Angèle Reinders and Pierre Verlinden, Wiley-Blackwell (2017) ISBN-13: 978-1118927465 and “Organic-Inorganic Halide Perovskite Photovoltaics: From Fundamentals to Device Architectures” edited by Nam-Gyu Park et al., Springer (2016) ISBN-13: 978-3319351124.

The perovskite can be formulated with or without the use of SnF₂, as further explained in the Examples section below. SnF₂ has been reported to successfully suppress oxidation in tin/lead perovskites by introducing a Sn-rich environment, namely by reducing Sn⁴⁺vacancies via the selective complexation by fluoride ions of Sn⁴⁺in the form of SnF₄ (Pascual et al., “Fluoride Chemistry in Tin Halide Perovskites”, Angewandte Chemie International Edition, Vol. 60, 39, 2021).

In a preferred device of the present invention, the photoactive layer is a compact layer without open porosity.

Methods for producing the devices of the invention are as further described in WO2016/198889.

During manufacture of devices according to the invention, wherein a solid layer of the perovskite material is produced, a step of curing the solid layer of the perovskite material may take place. The step of curing the solid layer of the perovskite material would typically involve heating the solid layer of the perovskite material to an elevated temperature for a set period of time, wherein the temperature and time period used for the curing step depends upon the specific composition of the perovskite material. In this regard, the skilled person would readily be able to determine an appropriate temperature and time period for the curing a solid layer of a perovskite material by using well-known procedures which do not require undue experimentation. In particular, it is noted that the skilled person will be aware that the exact temperature and time period used for the curing step will depend on variations in the equipment and apparatus used to perform the curing step, such that the selection of the values for these parameters is a matter of routine for the skilled person.

The invention will now be illustrated by the following Examples.

### EXAMPLES

### Fabrication of Thin Film and Devices—Mixed Cations

### Materials

The discussed thin films and devices of the compositions were all fabricated using SnI₂ (99.999% purity) and PbI₂ (99.999% purity) from Alfa Aesar. Methylammonium Iodide (MAI) and Ethylammonium Iodide (EAI) were purchased from Greatcell Solar. Acetamidinium Iodide, Diethylammonium Iodide, Immidazolium Iodide, PEDOT:PSS (AI 4083) and Phenyl-C61-butyric acid methyl ester (PCBM) were from Ossila. Guanidinium Iodide was from Sigma-Aldrich and Bathocuproin (BCP) was from Alfa Aesar. All the solvents used, N,N-Dimethylformamide (DMF), Dimethyl sulfoxide (DMSO), Chlorobenzene, 1,2-Dichlorobenzene, Methanol and Isopropanol (IPA) were from Sigma Aldrich as well.

### Perovskite Precursor Solution

Depending on the composition, the precursor solution of 1M concentration was prepared by mixing the corresponding components, A cation ratios and Pb/Sn ratios, in a DMF:DMSO (4:1) solvent mixture. The solution was stirred and then used for spin-coating.

### Device Fabrication

The pre-patterned ITO glass substrates were sequentially cleaned using acetone and isopropanol and then treated with O₂— plasma. PEDOT:PSS solution in methanol (PEDOT:PSS:Methanol-1:2) was spin coated on ITO substrates at 4000 rpm for 40 sec and annealed at 150° C. for 10 minutes in air. After cooling, the substrates were transferred in a N₂-filled glovebox. The perovskite films were deposited for a total time of 20 sec, during which anisole (400 μL) was dropped as antisolvent. The substrates were then annealed for 10 minutes at 100° C. PCBM (20 mg/ml in CB:DCB (3:1)) was spun dynamically at 2000 rpm for 30 sec followed by annealing at 90° C. for 2 minutes. BCP (0.5 mg/ml in IPA) was subsequently deposited by a dynamic spinning process at 4000 rpm for 20 sec. Finally, 100 nm of Ag top electrode were thermally evaporated at a rate of 0.2 nm/sec.

### Example 1

The device stack comprised glass substrate/ITO/PEDOT:PSS (15 nm)/Perovskite/PCBM (20 nm)/BCP(5 nm)/Ag (150 nm).

1. EA_{0.2} MA_{0.8}Sn_{0.6}Pb_{0.4}I₃

PEDOT:PSS solution (Al 4083 —Ossila) was diluted in methanol (PEDOT:PSS/Methanol—1:2) and filtered with 0.45 μm glass fibre filter, then spin coated onto patterned ITO/glass substrates. During spinning, solution was dropped onto the substrate and spun for 40 s at 4000 rpm in air followed by annealing at 150° C. for 10 minutes.

Perovskite EA_{0.2} MA_{0.3}Sn_{0.6}Pb_{0.4}13: a 1M solution was prepared with EAI (20%) and MAI (80%) dissolved into DMF:DMSO (4:1). The solution was then transferred into a vial with PbI₂(40%) and SnI₂(60%) (both 99.999% from Sigma Aldrich) in order to form the final perovskite precursor solution. This perovskite solution was dropped onto the substrate and spun for 20 sec. Anisole was used as an antisolvent and was dropped after the spinning had begun. Then the films were annealed at 120° C. for 10 min.

PC60BM powder was dissolved into Chlorobenzene/Dichlorobenzene (3:1)−20 mg/ml concentration. The solution was filtered with a 0.2 μm PTFE filter and heated at 90° C. before use. Dynamic spinning took place at 2000 rpm for 30 sec. The samples were annealed at 90° C. for 2 minutes.

BCP(Bathocuproin) was dissolved into IPA with concentration of 0.5 mg/ml and then filtered with a 0.2 μm PTFE filter after stirring overnight. Dynamic spinning took place at 4000 rpm for 20 sec.

No annealing followed.

The Ag top electrode was evaporated (150 nm).

### Results

EA_{0.2}MA_{0.3}Sn_{0.6}Pb_{0.4}I₃ proved to form a highly textured low gap perovskite structure leading to functional devices reaching PCE up to 4.98%.

### Example 2

Initial trials of screening alternative A-cation combinations for low gap compositions based on tolerance factor calculations showed that EA_{0.3}MA_{0.7}Sn_{0.5}Pb_{0.5}I₃ is highly textured and a single-phase composition. With this composition as a starting point, the effect of Sn/Pb and EA/MA ratios was investigated. EA_{0.2}MA_{0.3}Sn_{0.6}Pb_{0.4}I₃ was found to be the most crystalline and highly oriented composition.

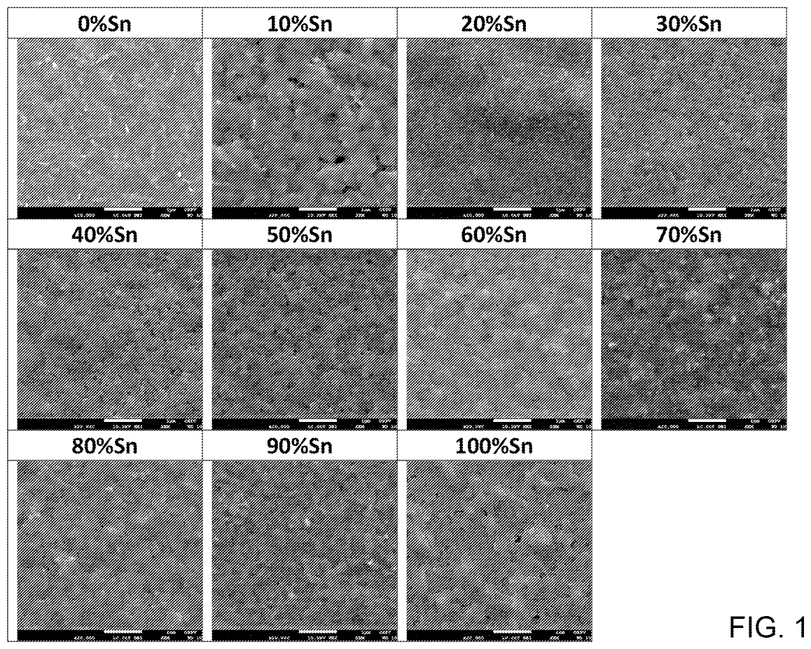

In order to define the range of Sn/Pb ratio that a perovskite structure can be formed, an experiment was conducted varying the percentage of Sn (0-100%) for the formula EA_{0.2}MA_{0.8}SnₓPb₁₋ₓI₃. XRD patterns, absorption spectra and SEM images for EA_{0.2}MA_{0.8}SnₓPb₁₋ₓI₃ (x=0-1) are shown in FIGS. 1A-1C.

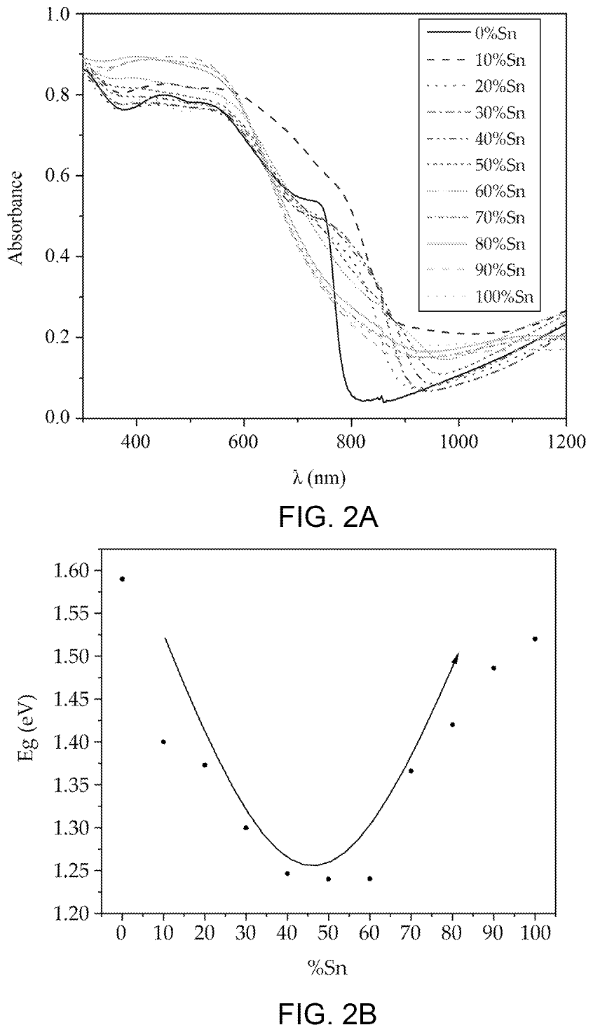

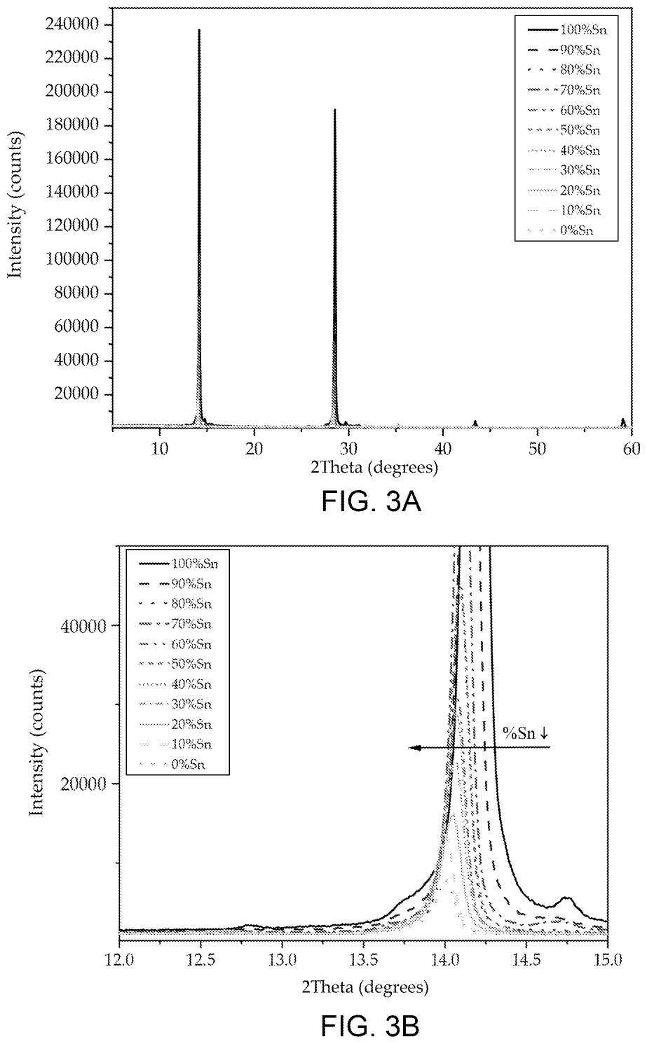

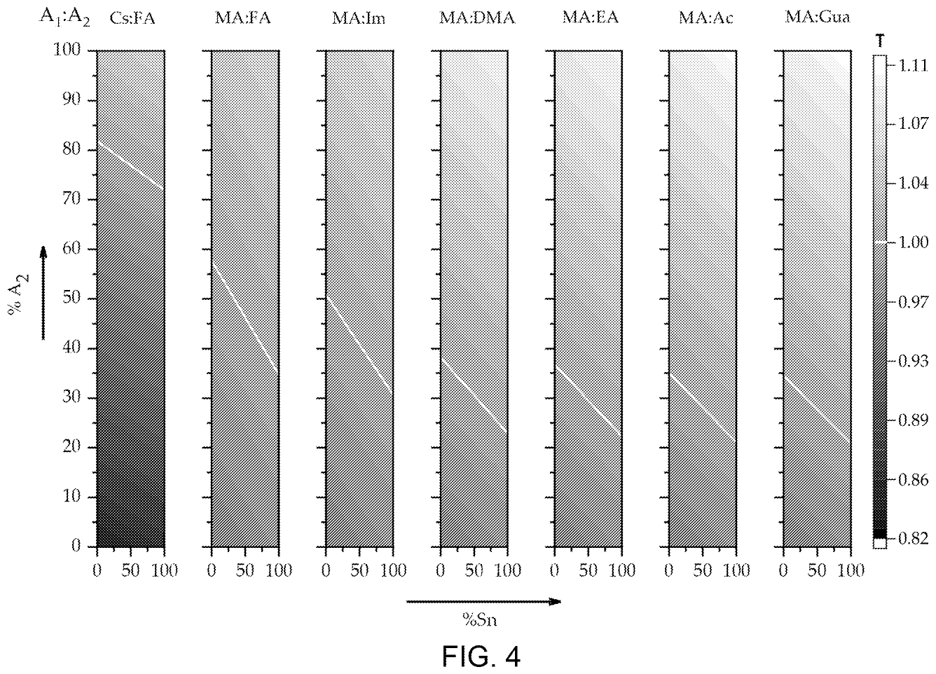

As indicated by the tolerance factor calculations (FIG. 4), a perovskite structure is formed for all different Sn percentages for fixed 20% EA. Interestingly, the anomalous band gap effect is also observed, with the lowest bandgap values lying between 40 and 60% Sn (FIG. 2B). Moreover, a shift of the main diffraction peak at 14° to higher 26 values with the inclusion of more Sn is observed, which is consistent with the expected lattice shrinking, since the Pb atom is larger than the Sn one (FIGS. 3A and 3B).

### Example 3

Following the above results, we searched for alternative large organic cations apart from EA (Ethyl ammonium) with similar ionic radii that might stabilize the structure (A′ₓMA_{1-X}Sn_{y}Pb_{1-y}I₃) as well (Table 1). Table 2 provides a list of typical perovskite cations for the A site in the general formula AMX₃, such as MA, FA and Cs and their corresponding ionic radius for reference. The suitable A′ cations are shown in Table 1 above.

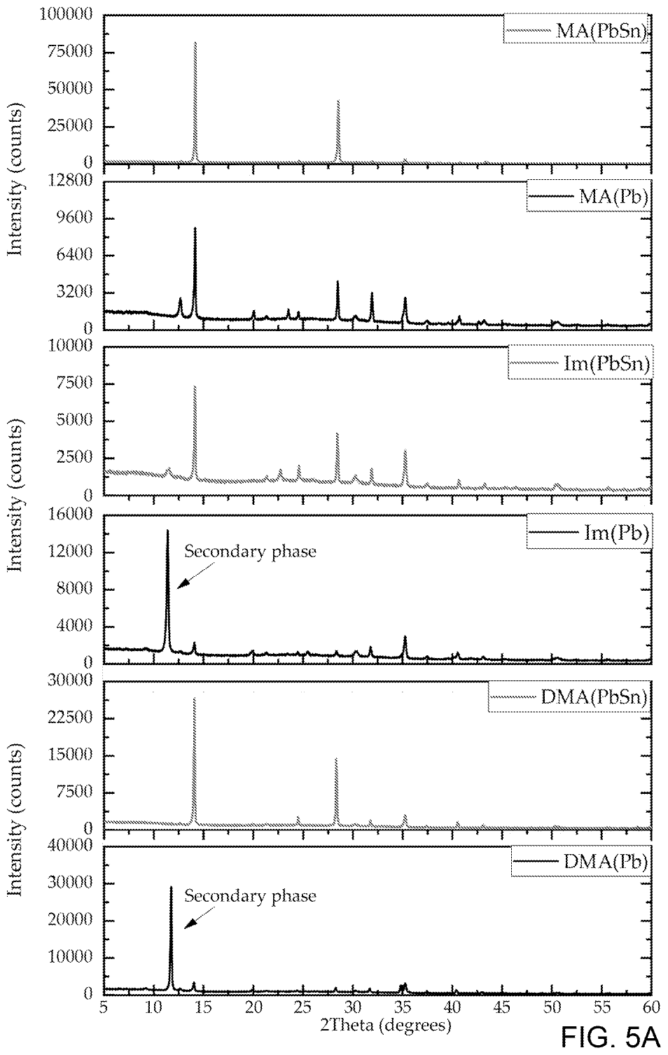

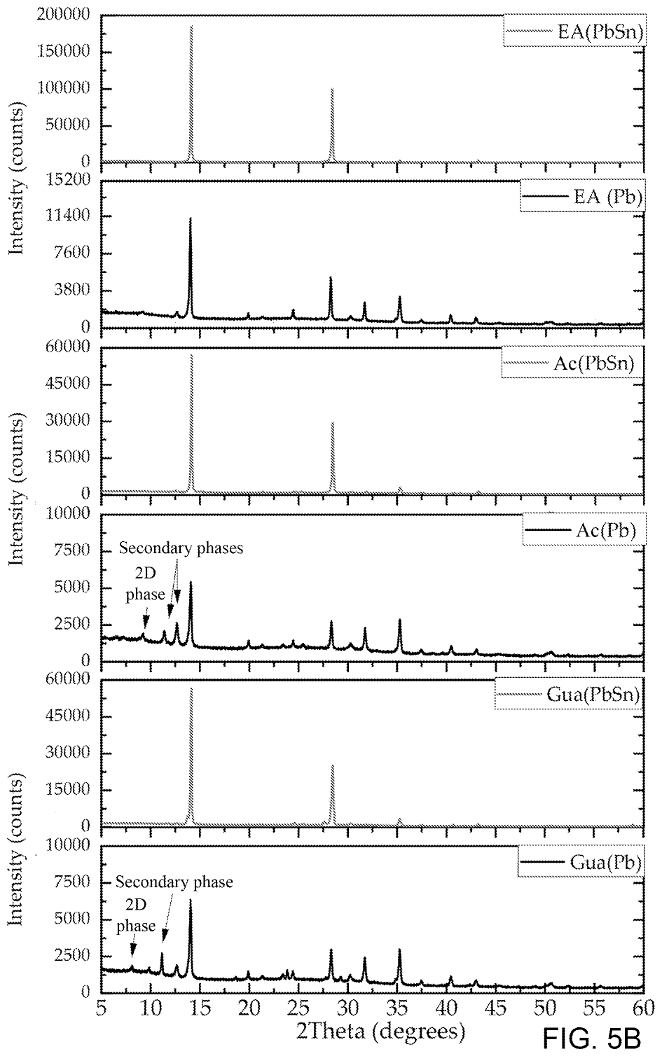

To first assess the stability of these cations with mixed Pb/Sn compositions, comparative XRDs with Pb alone were performed. Accordingly, a selection of A cations from Table 1, namely Im, DMA, EA, AD, Gua were investigated. As shown by FIG. 5, all Pb/Sn based samples clearly displayed greater stability, verified by the absence or diminished intensity of the PbI₂ peak at ˜12.5°; a characteristic degradation side-phase. Other impurity peaks are also observed to be eliminated for the Pb/Sn samples compared to the Pb alone samples, indicating better structural integrity within the explored processing space.

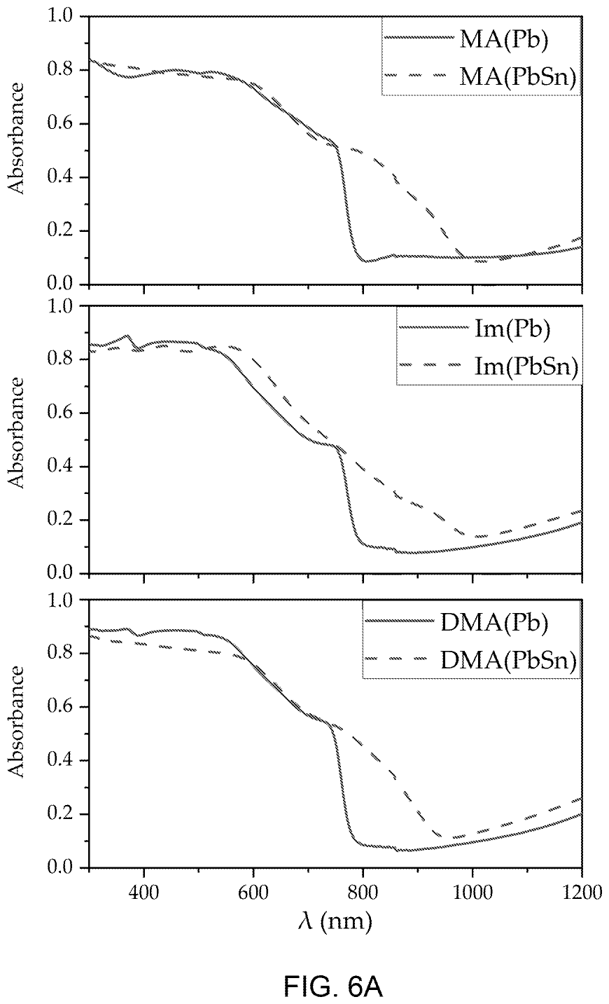

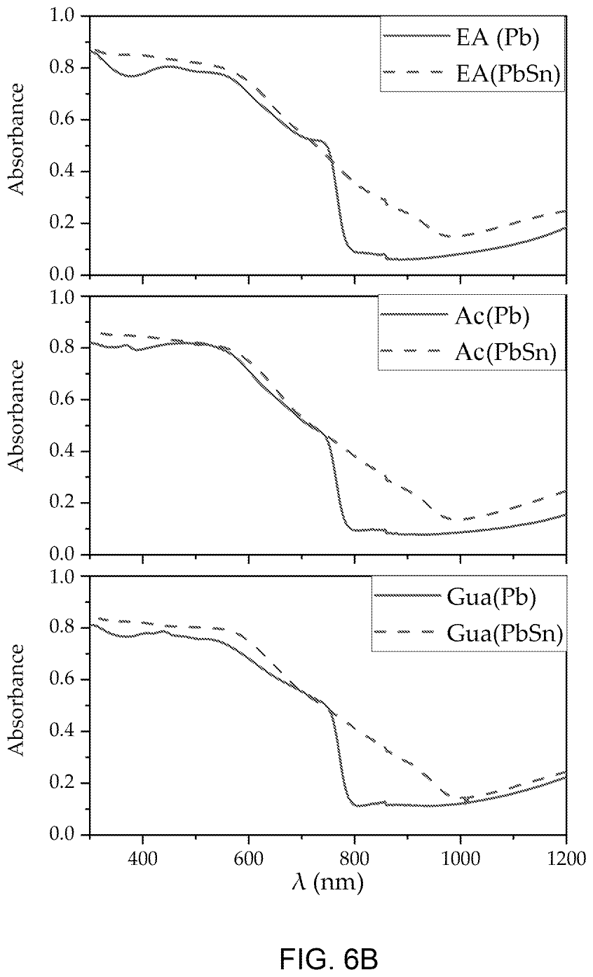

The absorbance capability of the same ions as above were also evaluated, illustrated by FIG. 6. In each case, the absorbance spectra were improved for the Pb/Sn compositions relative to the Pb counterpart, showing greater absorbance over a larger range of wavelengths.

Tolerance factor calculations were performed for various MA:A′ combinations, where A′ is one of the above cations from Table 1. The corresponding shaded maps were compared with the ones of the FA:Cs and MA:FA as well (FIG. 4). Since Sn is introduced into the structure, the amount of larger organic cation that could be incorporated decreases.

TABLE 2
Typical smaller A cations used in perovskite
structures and their corresponding ionic radii

| Monovalent | A cation | Ionic |
|---|---|---|
| Cation | type | radius (Å) |
| Methylammonium | A, | 2.16 |
| (MA) | organic | |
| Formamidinium | A, | 2.53 |
| (FA) | organic | |
| Cesium (Cs) | A″, | 1.67 |
| | inorganic | |

### Example 4

In order to ascertain if the inclusion of other larger organic cations could stabilise a low gap perovskite structure, compositions with tolerance factors similar to the one of EA_{0.2}MA_{0.3}Sn_{0.6}Pb_{0.4}I₃ with fixed 60% Sn were chosen to be tested experimentally (Table 3). The corresponding Pb-only compositions were examined and compared with the Pb/Sn counterparts.

TABLE 3
List of low gap compositions and their tolerance factor
values for 60% (y = 0.6) and 0% Sn (y = 0)

| Formula | T (y = 0.6) | T (y = 0) |
|---|---|---|
| EA_{0.2}MA_{0.8}Sn_{y}Pb_{1-y}I₃ | 0.991 | 0.98 |
| Im_{0.3}MA_{0.7}Sn_{y}Pb_{1-y}I₃ | 0.993 | 0.982 |
| DMA_{0.2}MA_{0.8}Sn_{y}Pb_{1-y}I₃ | 0.990 | 0.979 |
| AD_{0.2}MA_{0.8}Sn_{y}Pb_{1-y}I₃ | 0.992 | 0.981 |
| Gua_{0.2}MA_{0.8}Sn_{y}Pb_{1-y}I₃ | 0.993 | 0.981 |
| MASn_{y}Pb_{1-y}I₃ | 0.965 | 0.954 |

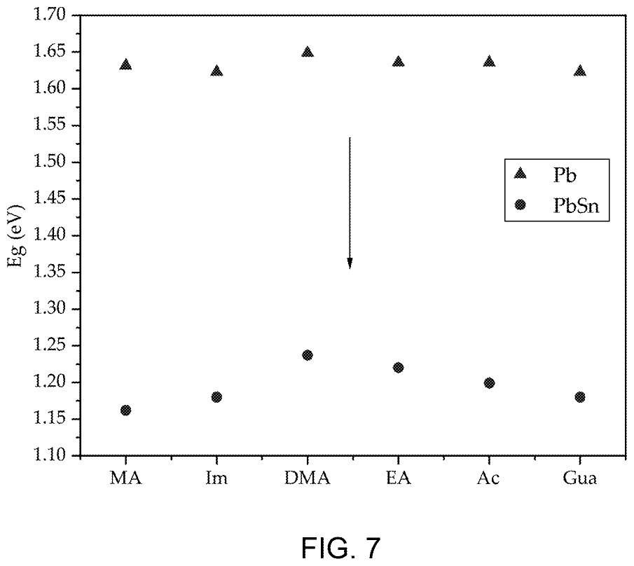

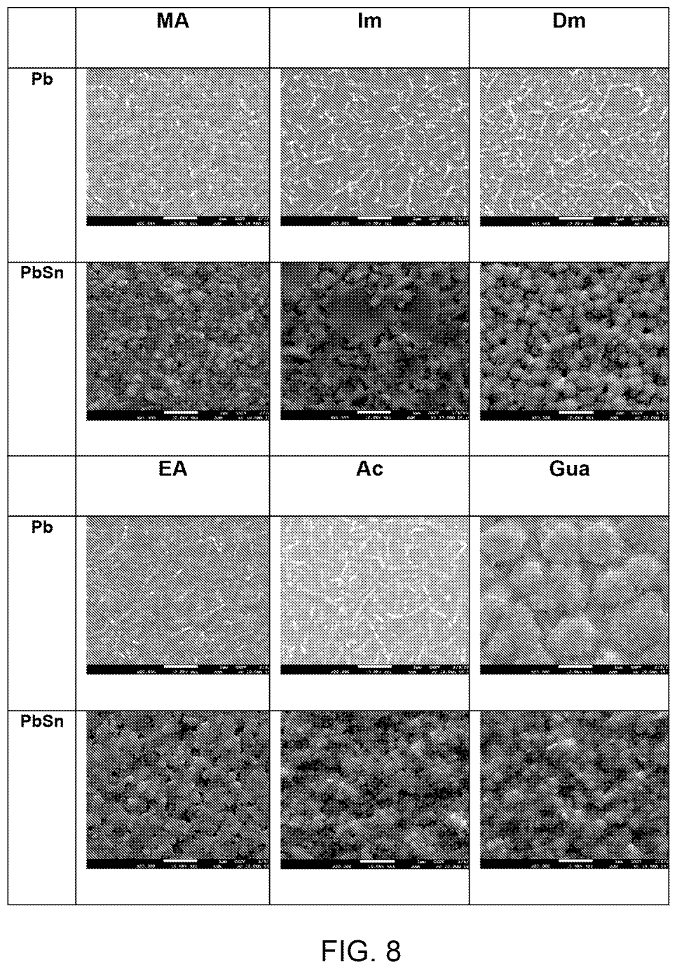

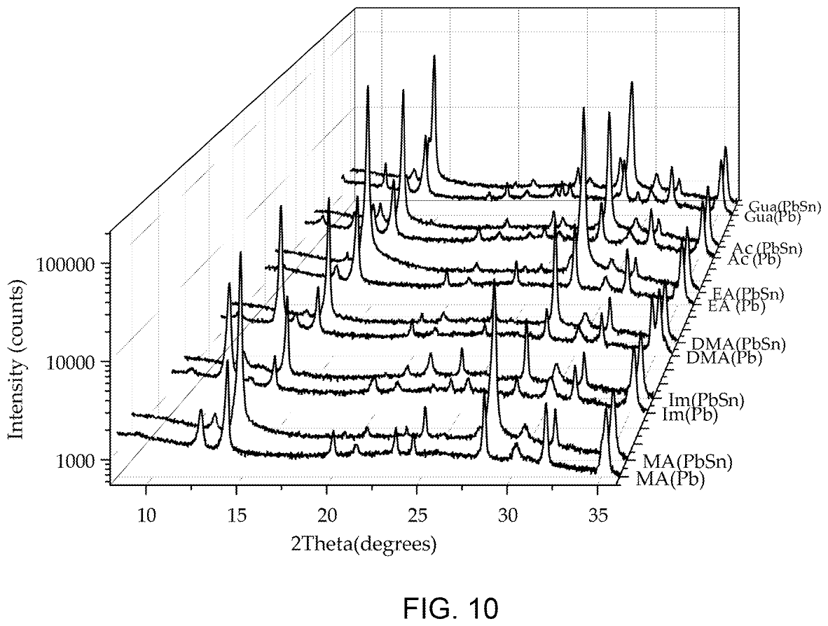

Interestingly, the compositions based only on Pb exhibit impurity phases, as was observed in the XRD patterns in FIG. 10 and the SEM images in FIG. 8. On the other hand, most of the mixed Pb—Sn compositions are highly oriented and textured without any secondary phases, despite the expectation that the smaller inorganic framework of the Pb—Sn perovskites would not be able to accommodate the larger cations. Based on the XRD patterns and the shifting of the main perovskite peak to higher 20, these larger cations occupy the “A”-site of the perovskite structure (corresponding to the A′ position in formula I). Thus, pure and highly textured Pb—Sn perovskites were formed. With regard to optical properties, although Sn addition governs the band gap reduction to the desired value range (1.2-1.3 eV), it seems that the band gap value can be fine-tuned by varying the A′-cation, as shown by FIG. 7.

### Example 5

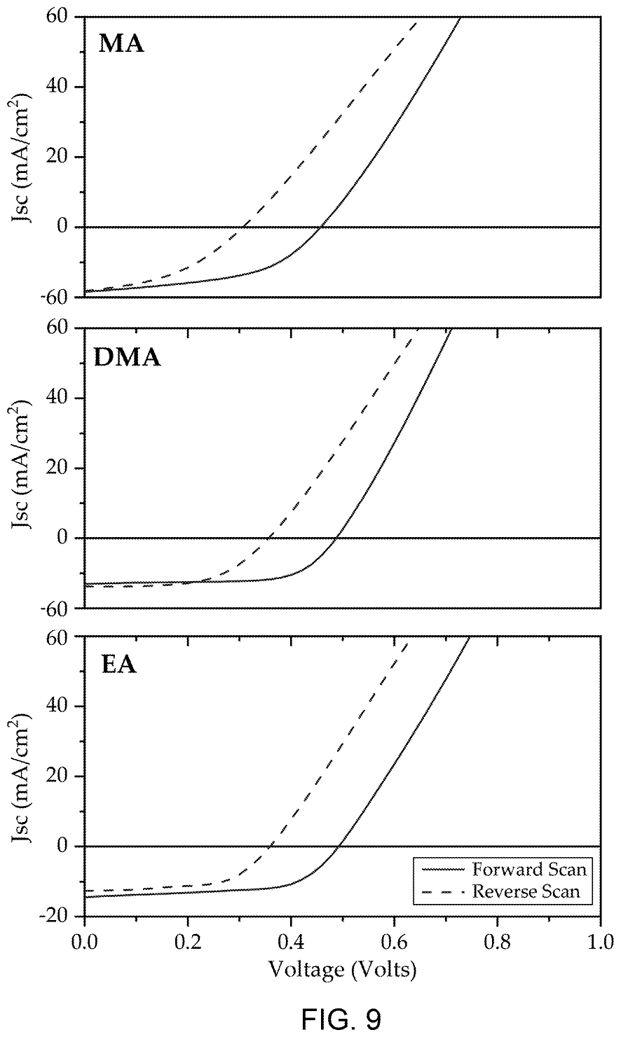

Devices were fabricated with the above compositions in Table 3. More specifically, the device configuration was Glass/ITO/PEDOT:PSS/Perovskite/PCBM/BCP/Ag. The results of the best devices of each case are presented in FIG. 9 and Table 4.

TABLE 4
Optimal efficiency of alternative low gap
perovskite compositions (according to Table 3)

| Formula | PCE (%) |
|---|---|
| EA_{0.2}MA_{0.8}Sn_{0.6}Pb_{0.4}I₃ | 4.9 |
| DMA_{0.2}MA_{0.8}Sn_{0.6}Pb_{0.4}I₃ | 4.5 |
| MASn_{0.6y} Pb_{0.41-y}I₃ | 4.5 |

The alternative EA-MA and DMA-MA structures exhibit similar efficiencies with respect to the MA-alone based composition (Table 4). Upon optimisation in a full device stack, where the materials are tuned to achieve favourable optical alignment, the larger cation-based devices in Table 4 show very promising potential to achieve PCEs comparable to those of standard lead-based perovskites.

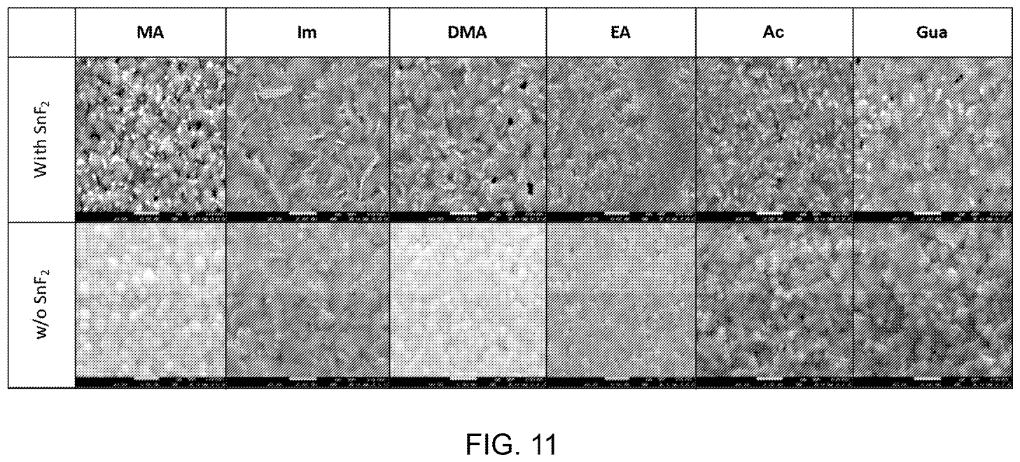

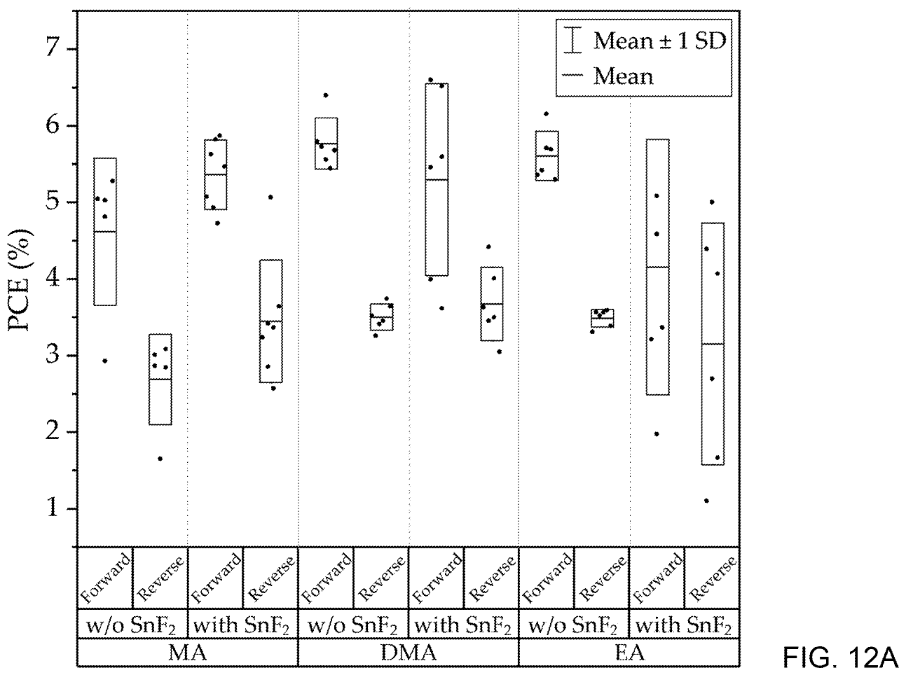

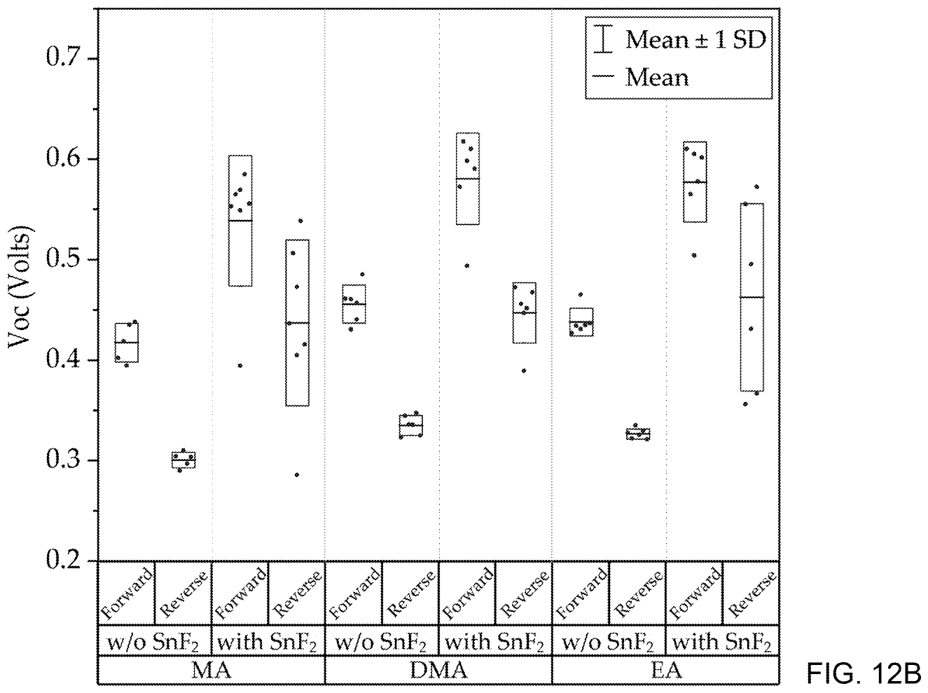

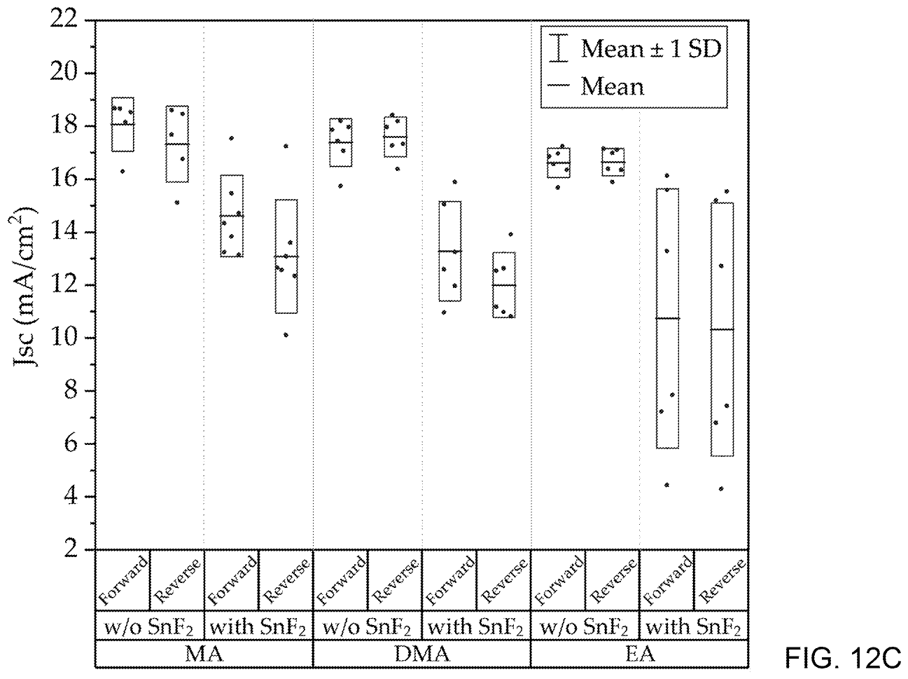

These devices were also compared to those containing SnF₂, shown by FIG. 12. Generally, the V_{OC} tended to be higher for devices with SnF₂, meanwhile the J_{SC} was greater for devices without SnF₂. The higher voltage with SnF₂ is likely attributed to the availability of Sn²⁺ compensating the Sn vacancies. However, the lower J_{SC} when SnF₂ is added could be due to more pinholes introduced into the structure, as shown by the morphologies in the SEM images of FIG. 11. The presence of pinholes can induce poorer crystallinity, thus impairing the current density.

Ultimately, SnF₂ can be a helpful agent to improve certain features of perovskites, such as the V_{OC} and humidity stability. In some scenarios however, SnF₂ can be a slight hindrance to the structural properties of a perovskite, thus careful deliberation with regards to alignment with specific perovskite compositions, and the amount of SnF₂ added must be considered when implementing this additive for mixed Pb—Sn perovskites.

### Example 6

The thermal stability and resilience to humidity exposure was also examined for each respective structure outlined in Table 3 alongside a direct comparison with and without the presence of SnF₂. Thermal stability was measured by applying 85° C. heat in a nitrogen atmosphere and measuring the relative intensity of the main (100) perovskite peak at 0 hours, 24, hours and 48 hours. Similarly, the humidity stability was also measured at these time intervals but instead under the condition of 40% relative humidity.

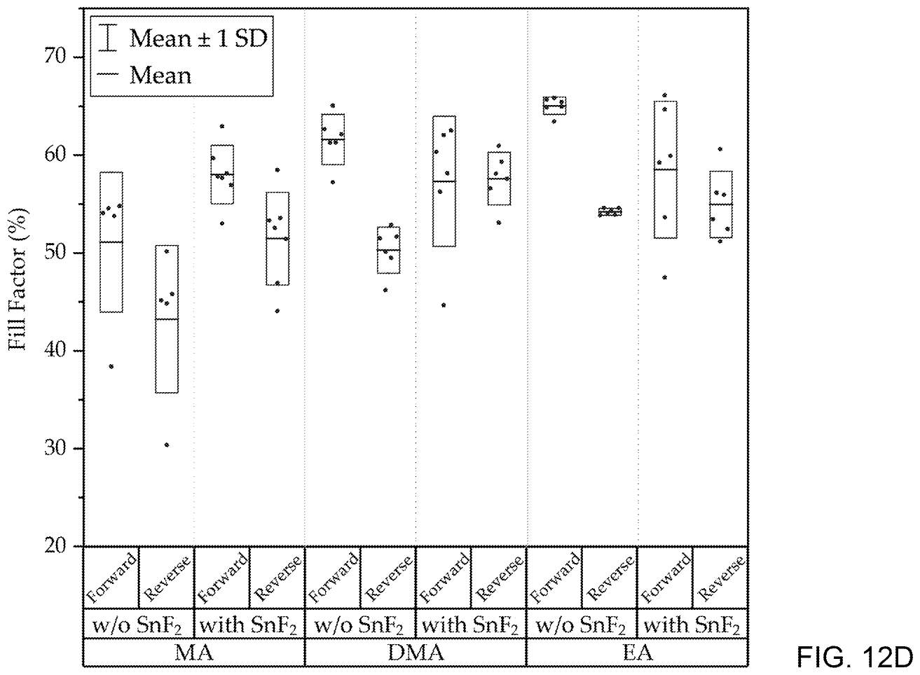

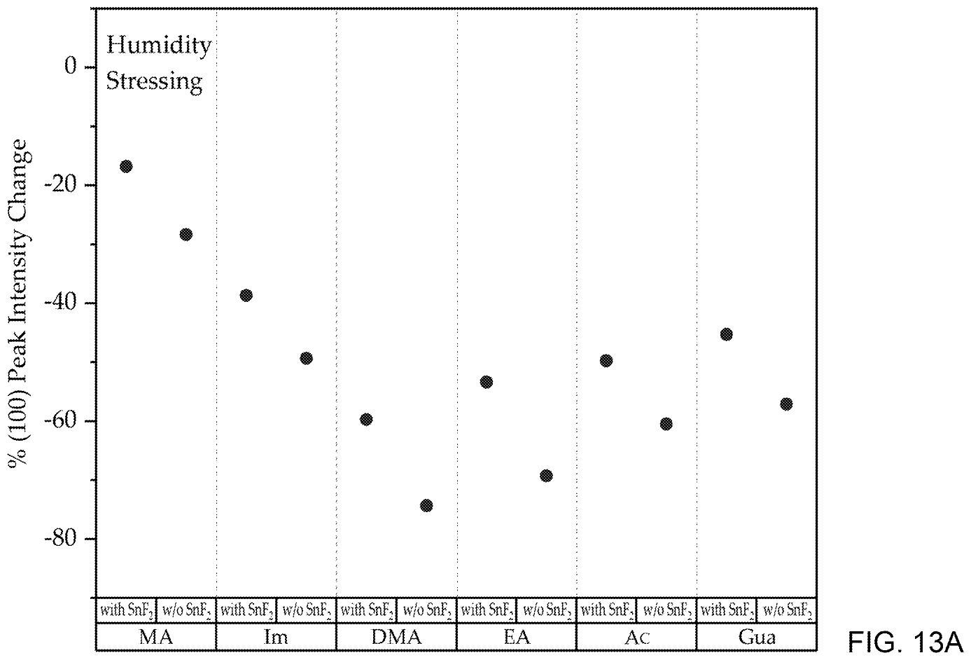

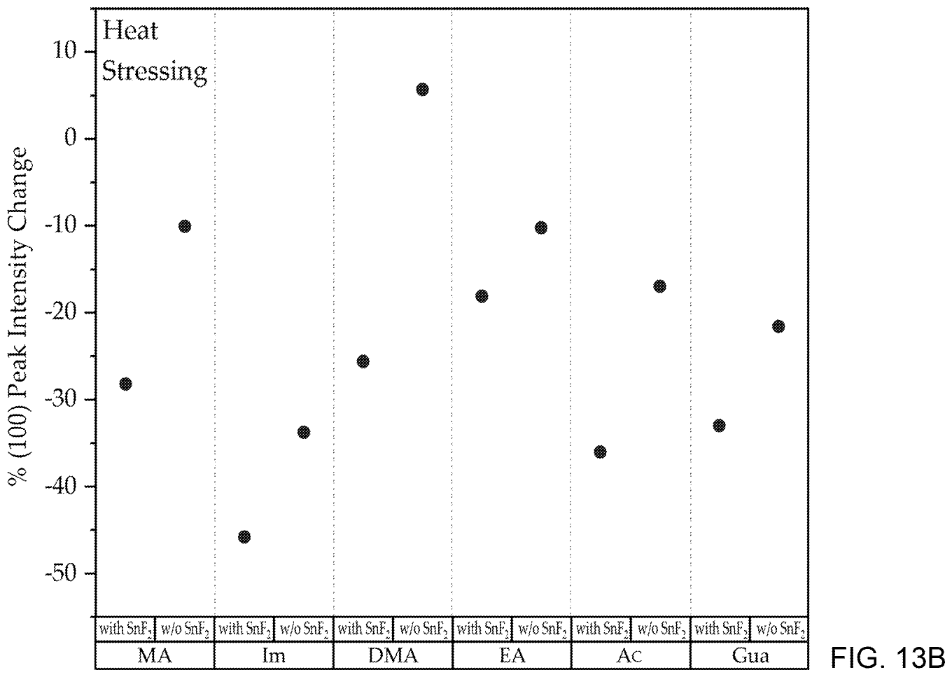

FIG. 13A provides a summary of the intensity change of the main (100) XRD perovskite peak of larger A cations with and without SnF₂, under humidity exposure. The humidity resilience was determined by the % change in the (100) peak intensity. In each case, the presence of SnF₂ appeared to slightly delay degradation, indicated by a smaller change in the peak intensity.

The same measurements were executed to investigate thermal stability of these large A cation perovskites. The presence of degradation product, PbI₂ was observed under heating with and without SnF₂ for every cation. For the main (100) peak however, it appeared in the XRDs that all of the compositions without SnF₂ experienced a slower drop in intensity under heat treatment compared to its SnF₂ counterpart, hence the lower overall change in intensity shown by FIG. 13B. Therefore, the materials without SnF₂ displayed improved structural integrity under heat treatment compared to those with SnF₂.

Overall, the compounds without SnF₂ exhibited poorer humidity stability but enhanced thermal stability. However, often humidity-induced degradation can be prevented by proper encapsulation, whereas thermal stressing is inevitable in a solar module.

In conclusion, the results from Examples 5 and 6 show that SnF₂ can be incorporated to improve certain characteristics but may not always be necessary depending on other features of the devices and particular conditions.

### Example 7

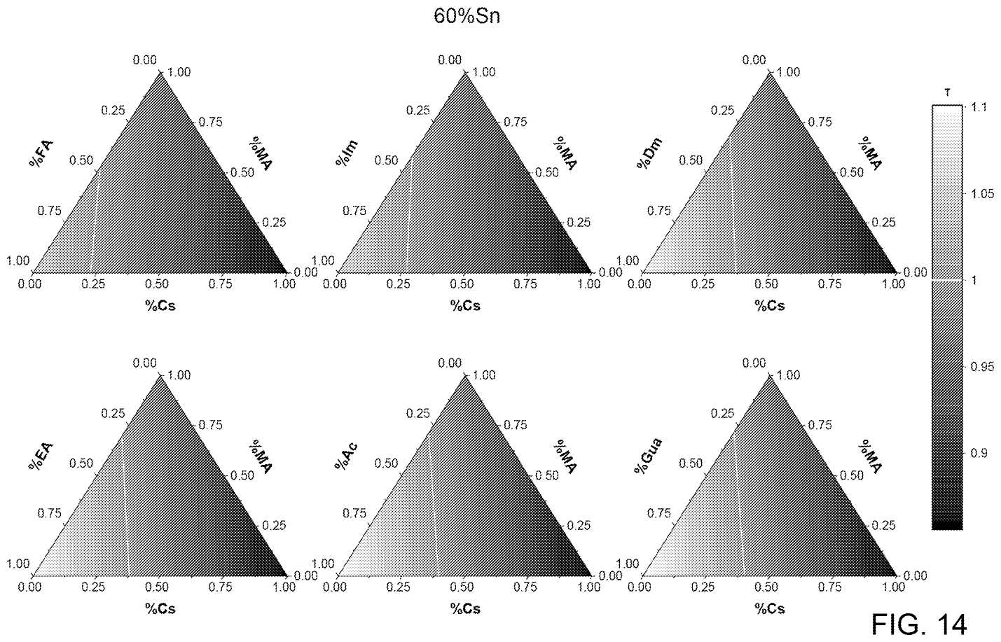

Tolerance factor calculations were performed for the triple cation structure (A′ₓMA_{y}Cs_{1-y-x}Sn_{y}Pb_{1-y}I₃), wherein Sn is present at 60% and A′ₓ may be any large cation according to Table 1. More specifically, the effect of Cs addition in double A-cation perovskites consisting of MA and a large A′ cation, such as Im, DMA, EA, Ac and Gua were examined. The results were displayed as shaded triangle maps, as shown by FIG. 14. The FA and Im cations were generally stabilized at compositions of more than 50% of these ions, with MA and Cs at approximately less than 50% and 25% respectively. For EA, Dm, Ac and Gua, these ions displayed an appropriate tolerance factor range at above ˜30% presence in the composition, with MA and Cs at approximately less than 70% and 37.5%, respectively. Generally, with a Cs percentage up to 30%, a proper arrangement of the A′/MA ratio, and an A′ percentage of 50-60%, τ=1 can be achieved. More Cs will lower the T value below 1, while higher A′ content will lead to values over 1. Thus, optimisation of the ratio of each of the three A cations allows for tolerance factors in the desirable range 0.8<τ<1.

The experimental tolerance factor values for a variety of triple cation compounds with large cations Im, DMA, EA and Gua are displayed below in Table 5. A reference composition, EA-_{0.2}MA_{0.8}Sn_{0.6}Pb_{0.4}I₃ which has a tolerance factor of 0.991, has high texturing, and has shown successful integration in a functional device, was used as a guide for selecting the triple cation compositions.

TABLE 5
Tolerance factors of triple cation compositions
and the reference composition selected
for experimental trials.

| Compositions | Tolerance Factor |
|---|---|
| EA_{0.2}MA_{0.8}Sn_{0.6}Pb_{0.4}I₃ | 0.991 |
| (Reference composition) | |

Triple Cation—Various triplets

| | |
|---|---|
| Cs_{0.1}DMA_{0.3}MA_{0.6}Sn_{0.6}Pb_{0.4}I₃ | 0.992 |
| Cs_{0.1}EA_{0.3}MA_{0.6}Sn_{0.6}Pb_{0.4}I₃ | 0.993 |
| Cs_{0.1}Im_{0.4}MA_{0.5}Sn_{0.6}Pb_{0.4}I₃ | 0.992 |
| Cs_{0.2}Gua_{0.35}MA_{0.45}Sn_{0.6}Pb_{0.4}I₃ | 0.992 |

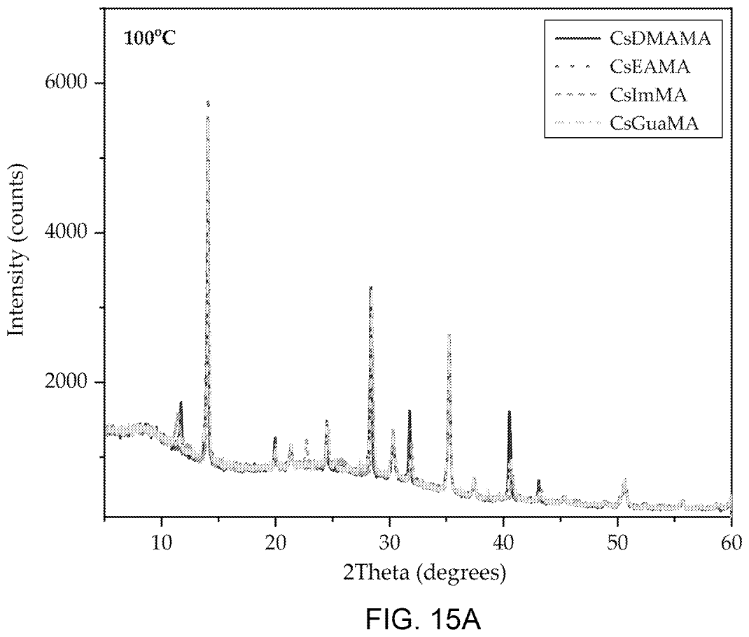

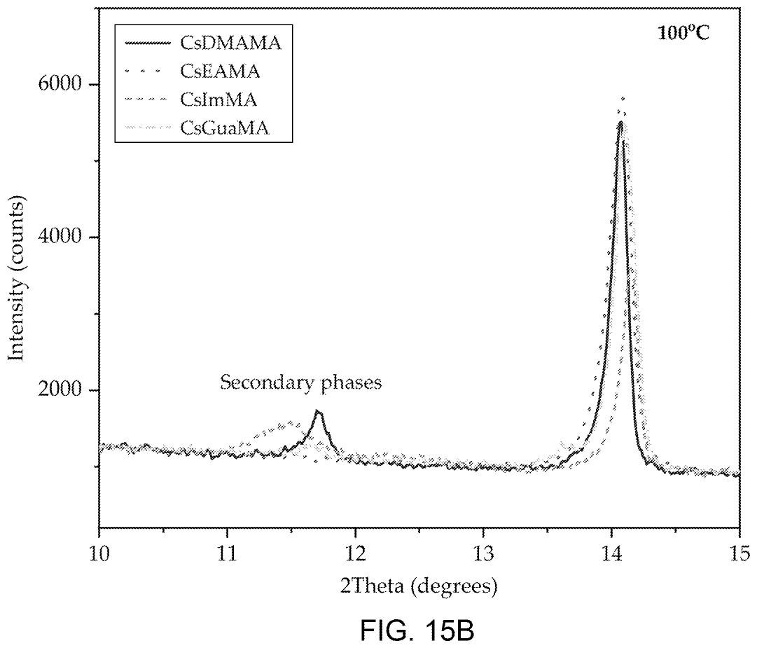

XRDs of the compositions in Table 5 were then taken and confirmed that all compounds successfully formed the perovskite phase, as shown by FIGS. 15A and 15B. Cs_{0.1}EA_{0.3}MA_{0.6}Sn_{0.6}Pb_{0.4}I₃ appears to be the purest phase, with no extra peaks observed, while Cs_{0.1}Im_{0.4}MA_{0.5}Sn_{0.6}Pb_{0.4}I₃ displayed the most impurity peaks. In addition, both Cs_{0.1}DMA_{0.3}MA_{0.6}Sn_{0.6}Pb_{0.4}I₃ and Cs_{0.2}Gua_{0.35}MA_{0.45}Sn_{0.6}Pb_{0.4}I₃ exhibited a secondary phase peak around 11.5-12°.

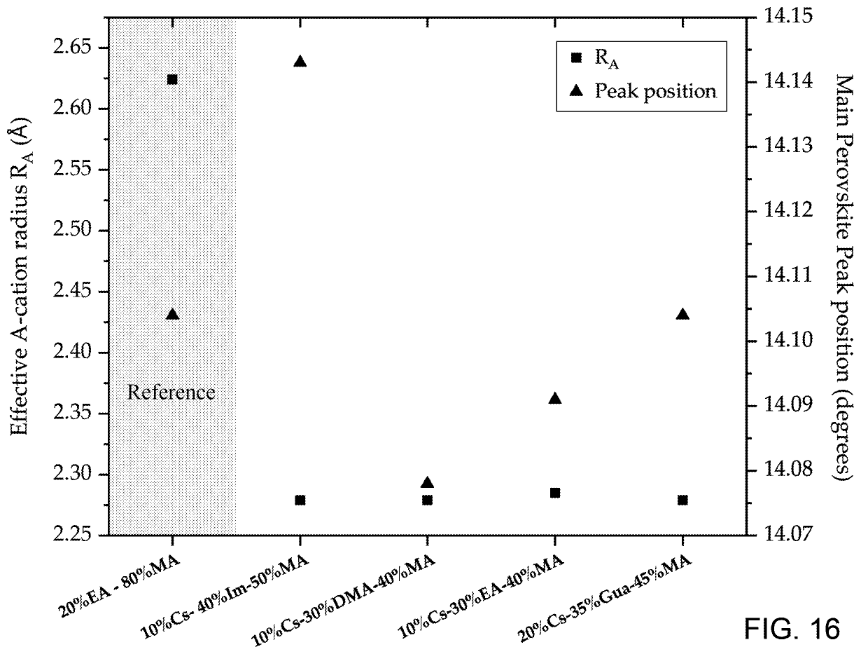

Furthermore, the effective A cation radius, R_{A} and associated main perovskite peak position for each of the compositions listed in Table 5 are illustrated by FIG. 16. Although all of the triple cation compositions have similar R_{A} values, variations in the peak position and accordingly to the unit cell size are nonetheless observed amongst the group. For example, Cs_{0.1}DMA_{0.3}MA_{0.6}Sn_{0.6}Pb_{0.4}I₃ and Cs_{0.1} EA_{0.3}MA_{0.6}Sn_{0.6}Pb_{0.4}I₃ which used the same ratio of A-cations, experienced different peak position shifts with respect to the reference composition, whereby the EA compound saw a significantly greater positional shift to higher 29 and hence unit cell shrinkage than the triple cation DMA compound. This indicates that the geometry and interactions of each large cation incorporated into the lattice play a highly influential role on the final perovskite structure.

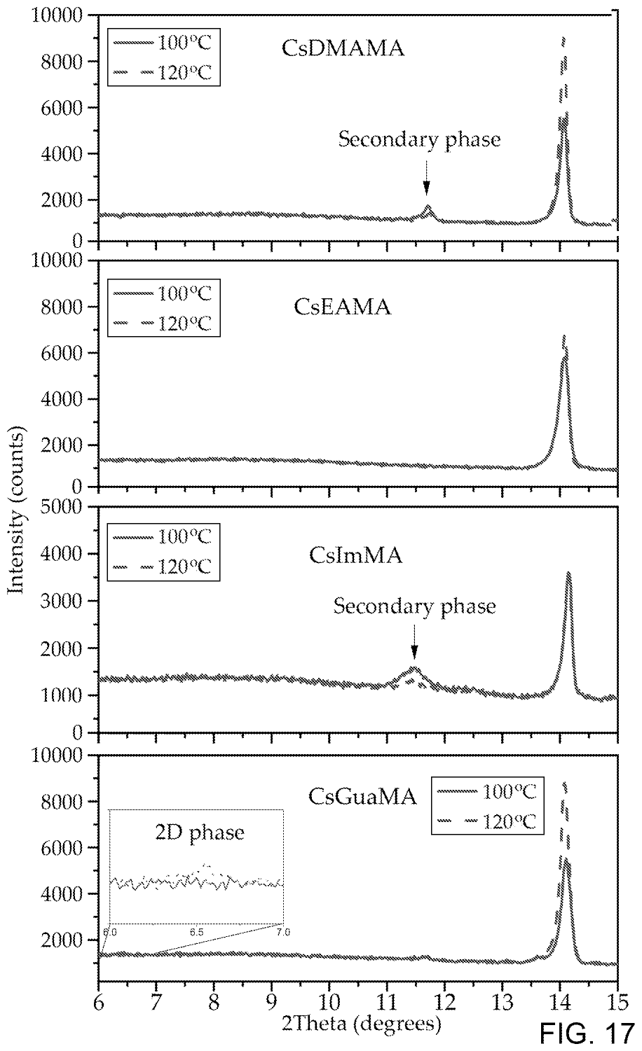

The effect of annealing temperature was also investigated. The XRD patterns of each composition annealed at 100° C. and 120° C. are presented in FIG. 17. Annealing the compositions at the higher temperature led to increased crystallinity and partial suppression of the secondary phase peaks appearing in the low θ range. Interestingly, for Cs_{0.2}Gua_{0.35}MA_{0.45}Sn_{0.6}Pb_{0.4}I₃, a 2D-phase related peak appeared around 6.5° when the sample was annealed at the higher temperature.

Triple cation mixed Pb/Sn perovskites with a favourable tolerance factor can successfully be formed, adopting slightly different structures depending on the large A cation. Thus, optimization of the fabrication conditions for each unique composition will enable improved material quality and overall purity.

### Example 8

Furthermore, the effect of adding in trace amounts of Cs to the reference double-cation composition EA_{0.2}MA_{0.8}Sn_{0.6}Pb_{0.4}I₃ was investigated. The EA/MA ratio was kept constant with the introduction of Cs in amounts of 1%, 3% and 5%, giving the compositions listed below in Table 6.

TABLE 6
List of triple cation compositions examined with trace amounts of Cs.
Triple cation—Traces of Cs
Cs_{0.01}EA_{0.198}MA_{0.792}Sn_{0.6}Pb_{0.4}I₃
Cs_{0.03}EA_{0.194}MA_{0.776}Sn_{0.6}Pb_{0.4}I₃
Cs_{0.05}EA_{0.19}MA_{0.76}Sn_{0.6}Pb_{0.4}I₃

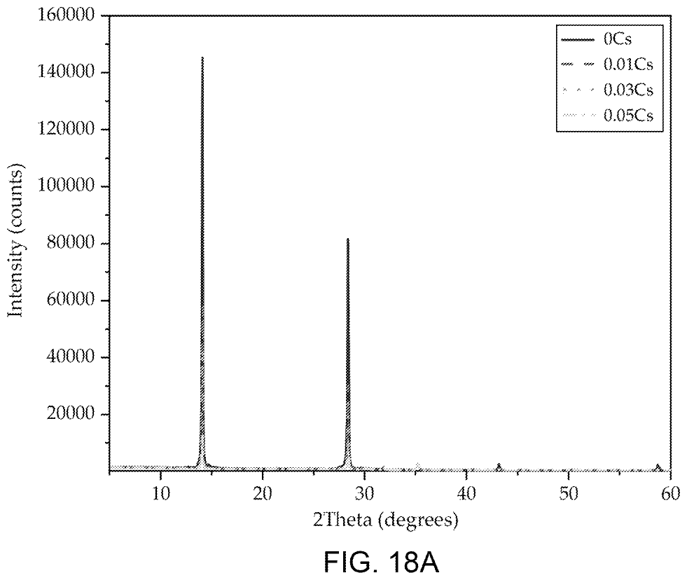

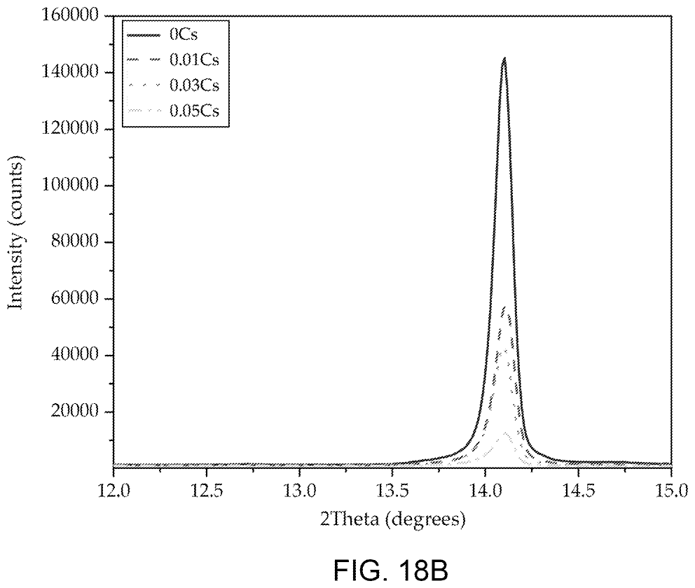

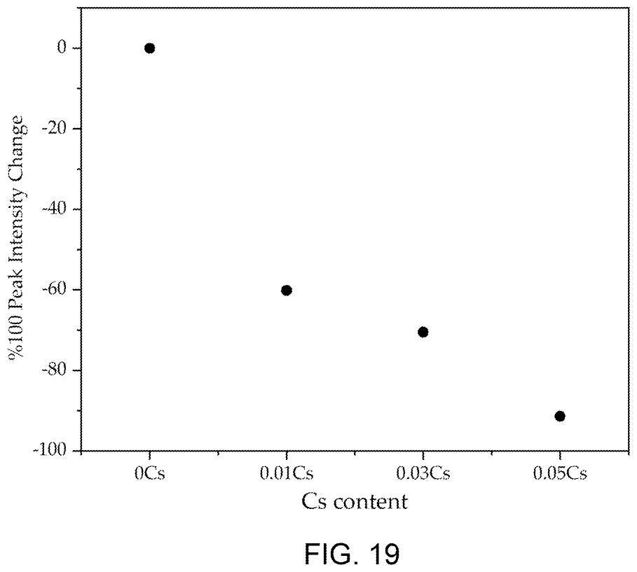

XRD was then carried out on the compositions detailed in Table 6 along with the reference composition, as shown by FIGS. 18A and 18B (close-up on 12-15° range). Evidently, the high texturing observed for the reference composition is retained when Cs is added in the selected amounts, verified by the absence of any additional peaks when Cs is incorporated. The intensity of the ˜14° peak from FIG. 18B was then examined for each compound (FIG. 19). A significant decrease in the peak intensity is observed for each Cs amount, even when 0.01 Cs is added in the structure. However, since no significant peak shifting is present, lattice shrinkage or enlargement did not occur, indicating stabilised structures.

1. A perovskite material having the formula (I):
AₐA′_{b}A″_{c}Sn_{(y)}Pb_{(1-y)}X₃ (I)
wherein A consists of a monovalent cation
A′ consists of a monovalent organic cation having an ionic radius greater than 2.53 Å;
A″ consists of a monovalent inorganic cation;
X comprises one or more halide anions;
0<a<1;
0<b<1;
0≤c<1;
a+b+c=1; and
0<y<¹.

2. The perovskite material according to claim 1 wherein A consists of a monovalent organic cation and is selected from methylammonium (MA, CH₃NH₃⁺), formamidinium (HC(NH)₂)₂⁺), and ethyl ammonium (CH₃CH₂NH₃⁺).

3. The perovskite material according to claim 1 wherein 0.03<b<1.

4. The perovskite material according to claim 1, wherein A′ is a monovalent organic cation selected from ethyl ammonium (EA), imidazolium, guanidinium, dimethyl ammonium, and acetamidinium.

5. The perovskite material according to claim 1, wherein X comprises one or more halide anions selected from I, Br and F.

6. The perovskite material according to claim 1, wherein 0.2<y<0.7.

7. The perovskite material according to claim 1, wherein 0<c<1.

8. The perovskite material according to claim 7, wherein A″ is Cs⁺ or Rb⁺.

9. The perovskite material according to claim 1, wherein c is zero, such that the formula of the perovskite is AₓA′₁₋ₓSn_{y}Pb_{(1-y)}X₃, wherein 0<x<1.

10. The perovskite material according to claim 9 in which 0.03<x<1.

11. The perovskite material according to claim 9 of formula (EA)₍ₓ₎(MA′)₍₁₋ₓ₎Sn_{(y)}Pb_{(1-y)}X₃.

12. The perovskite material according to claim 11 of formula EA₍ₓ₎MA′₍₁₋ₓ₎Sn_{(y)}Pb_{(1-y)}I₃.

13. The perovskite material according to claim 1, wherein c is greater than zero, such that the formula of the perovskite is AₐA′_{b}A″_{c}Sn_{y}Pb_{(1-y)}X₃, wherein
A is a monovalent organic cation;
a+b+c=1;
0<a<1;
0<b<1;
0<c<1;
and
0<y<1.

14. The semiconductor device having a photoactive region comprising a perovskite material as claimed in claim 1.

15. The semiconductor device according to claim 14, wherein the semiconductor device is a photovoltaic device having a photoactive region.

16. The photovoltaic device according to claim 15, wherein the photoactive region comprises a thin film of the perovskite material having a thickness in the range from 100 nm to 1500 nm.

17. The photovoltaic device according to claim 15, wherein the photoactive region comprises: an n-type region comprising at least one n-type layer; and a layer of the perovskite material in contact with the n-type region.

18. The photovoltaic device according to claim 15, wherein the photoactive region comprises: an n-type region comprising at least one n-type layer;
a p-type region comprising at least one p-type layer; and
a layer of the perovskite material disposed between the n-type region and the p-type region.

19. The photovoltaic device as claimed in claim 16 in which the photoactive layer is a compact layer without open porosity.

20. The multijunction photovoltaic device comprising two or more sub-cells, the first sub cell comprising a photovoltaic device as claimed in claim 16, and a further sub-cell comprising a photoactive layer having a bandgap of between 1.5 and 1.9 eV.
